(19) United States
(12) Patent Application Publication
(10) Pub. No.: US 2025/0204173 A1
(43) Pub. Date: Jun. 19, 2025

(54) DISPLAY DEVICE

(71) Applicant: LG DISPLAY CO., LTD., Seoul (KR)

(72) Inventors: Kyung Jae YOON, Paju si (KR); Seung Han PAEK, Paju si (KR); Jeon Phill HAN, Paju si (KR); Yu Cheol YANG, Paju si (KR); Nam Woo KIM, Paju si (KR)

(73) Assignee: LG DISPLAY CO., LTD., Seoul (KR)

(21) Appl. No.: 18/820,046

(22) Filed: Aug. 29, 2024

(30) Foreign Application Priority Data
Dec. 14, 2023 (KR) 10-2023-0181745

(51) Int. Cl. H10K 59/124; H10K 59/80

(52) U.S. Cl. CPC H10K 59/124; H10K 59/873

(57) ABSTRACT

A display device includes a display panel including a display area, a light-transmissive area, and a non-display area surrounding the light-transmissive area, and a sensor disposed in the light-transmissive area. The display panel includes a substrate, a circuit portion and a light-emitting element part on the substrate in the display area, an upper protective layer on the substrate in the non-display area, and a plurality of protruding patterns on the upper protective layer. The substrate includes an opening at a position corresponding to the light-transmissive area.

### CROSS-REFERENCE TO RELATED APPLICATION

This application claims priority to and the benefit of Korean Patent Application No. 10-2023-0181745, filed Dec. 14, 2023, the disclosure of which is incorporated herein by reference in its entirety.

### BACKGROUND

### Technical Field

The present specification relates to a display device.

### Discussion of the Related Art

Electroluminescence display devices are classified into inorganic light-emitting display devices and organic light-emitting display devices depending on materials of the emission layer. An active-matrix-type organic light-emitting display device includes an organic light-emitting diode (OLED) that emits light by itself and has advantages of a quick response time, high light emission efficiency, high luminance, and a wide viewing angle. The organic light-emitting display device has OLEDs formed in each pixel. The organic light-emitting display device may represent a black grayscale as perfect black as well as having a quick response time, high light emission efficiency, high luminance, and a wide viewing angle, and thus has an excellent contrast ratio and color gamut.

Recently, an organic light-emitting display device has been implemented on a plastic substrate made of a flexible material, but may also be implemented on a glass substrate due to various issues.

However, when a laser is used to form a notch on a glass substrate or a hole inside a display panel, the display panel may be damaged by the laser, or moisture, oxygen, or the like may penetrate into the interior of the display panel due to such damage.

### SUMMARY

Accordingly, embodiments of the present disclosure are directed to a display device that substantially obviates one or more of the problems due to limitations and disadvantages of the related art.

An aspect of the present disclosure is to provide a display panel that improves quality and reliability by preventing damage due to a laser, and a display device including the same.

Another aspect of the present disclosure is to provide a display panel having an improved structure for preventing damage due to an etching process, and a display device including the same.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device may comprise a display panel including a display area, a light-transmissive area, and a non-display area surrounding the light-transmissive area, wherein the display panel includes: a substrate; a circuit portion and a light-emitting element part on the substrate in the display area; an upper protective layer on the substrate in the non-display area; and a plurality of protruding patterns on the upper protective layer, and wherein the substrate includes an opening at a position corresponding to the light-transmissive area a display panel.

In another aspect, a display device may comprise a display panel including a display area, a light-transmissive area, and a non-display area surrounding the light-transmissive area, wherein the display panel includes: a substrate having an opening at a position corresponding to the light-transmissive area; a circuit portion and a light-emitting element part on the substrate in the display area; a buffer layer on the substrate in the non-display area; a lower protective layer under the substrate in the non-display area; a planarization layer on the buffer layer; and a plurality of protruding patterns on the planarization layer, and wherein a distance from a center of the light-transmissive area to the lower protective layer is greater than a distance from the center of the light-transmissive area to the buffer layer.

According to example embodiments the present disclosure, quality and reliability can be improved by preventing damage caused by a laser. Accordingly, it is possible to prevent moisture, oxygen, or the like from penetrating into the interior of a display panel through a light-transmissive area.

According to example embodiments of the present disclosure, process optimization can be implemented by etching a part of a substrate through an etching process.

According to example embodiments of the present disclosure, when a substrate made of glass is etched, an upper protective layer can be used to prevent an etching solution from penetrating into the interior of a display panel.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a view illustrating a display device according to an embodiment of the present specification;

FIG. 2 is a cross-sectional view taken along line I-I′ in FIG. 1;

FIG. 3 is an enlarged view of a part A in FIG. 2;

FIG. 4 is a cross-sectional view taken along line II-II′ in FIG. 1;

FIG. 5 is a view illustrating a light-transmissive area and a protective layer surrounding an edge area of the light-transmissive area;

FIG. 6 is an enlarged view illustrating an area B in FIG. 5;

FIG. 7 is an enlarged view illustrating an area C in FIG. 6;

FIG. 8 is a view illustrating a display device according to an embodiment of the present specification;

FIG. 9 is an enlarged view illustrating an area D in FIG. 8;

FIG. 10 is an enlarged view illustrating an area E in FIG. 8;

FIG. 11 is a view illustrating a display panel before a light-transmissive area is formed;

FIGS. 12A to 12F are views illustrating a process of etching a substrate to form a light-transmissive area in a display panel;

FIG. 13 is a view illustrating an example of a protective layer disposed on a display device according to an embodiment of the present specification;

FIG. 14 is a view illustrating another example of a protective layer disposed on a display device according to an embodiment of the present specification;

FIG. 15 is a view illustrating still another example of a protective layer disposed on a display device according to an embodiment of the present specification;

FIG. 16 is a view illustrating yet another example of a protective layer disposed on a display device according to an embodiment of the present specification;

FIG. 17 is a view illustrating another example of a display panel before a light-transmissive area is formed;

FIGS. 18A to 18F are views illustrating a process of etching a substrate to form a light-transmissive area in a display panel on which a lower protective layer is disposed;

FIG. 19 is a view illustrating yet another example of a protective layer disposed on a display device according to an embodiment of the present specification;

FIG. 20 is a view illustrating yet another example of a protective layer disposed on a display device according to an embodiment of the present specification; and

FIG. 21 is a view illustrating yet another example of a protective layer disposed on a display device according to an embodiment of the present specification.

### DETAILED DESCRIPTION

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure. The present disclosure is only defined within the scope of the accompanying claims.

Shapes, sizes, ratios, angles, numbers, and the like disclosed in the drawings for describing the embodiments of the present disclosure are exemplary, and the present disclosure is not limited to the illustrated items. Like reference numerals refer to like elements throughout.

In addition, in describing the present disclosure, if it is determined that the detailed description of the related known technology may unnecessarily obscure the subject matter of the present disclosure, the detailed description thereof will be omitted.

The terms such as “comprising,” “including,” “having,” and “consisting of” used herein are generally intended to allow other components to be added unless the terms are used with the term “only.” References to the singular shall be construed to include the plural unless expressly stated otherwise.

In interpreting a component, it is interpreted to include an error range even if there is no separate description.

When describing a positional or interconnected relationship between two components, such as “on top of,” “above,” “below,” “next to,” “connect or couple with,” “crossing,” “intersecting,” etc., one or more other components may be interposed between them unless “immediately” or “directly” is used.

When describing a temporal contextual relationship is described, such as “after,” “following,” “next to,” or “before,” it may not be continuous on a time scale unless “immediately” or “directly” is used.

To distinguish between components, ordinal numbers such as first, second, and the like may be used before the name of the component, but the function or structure is not limited by these ordinal numbers or component names. For convenience of description, different embodiments may have different ordinal numbers preceding the names of the same component.

The following embodiments may be combined or associated with each other in whole or in part, and various types of interlocking and driving are technically possible. The embodiments may be implemented independently of each other or together in an interrelated relationship.

Throughout the specification, the same reference numerals refer to the same component.

As used herein, “a display device” may include a display device in a narrow sense, such as a liquid crystal module (LCM), an organic light-emitting diode (OLED) module, or a quantum dot (QD) module, which includes a display panel and a driver for driving the display panel. It may also include a set electronic apparatus or a set device or set apparatus, such as a laptop computer, a television set, a computer monitor, an automotive display apparatus or an equipment display apparatus including another form in a vehicle, and a mobile electronic apparatus, such as a smart phone or an electronic pad, which is a complete product or finished product including the LCM, the OLED module, and the QD module.

A display device in this disclosure may include a display device itself in a narrow sense, an application product including a display in a narrow sense, or even a set device that is an end-consumer device.

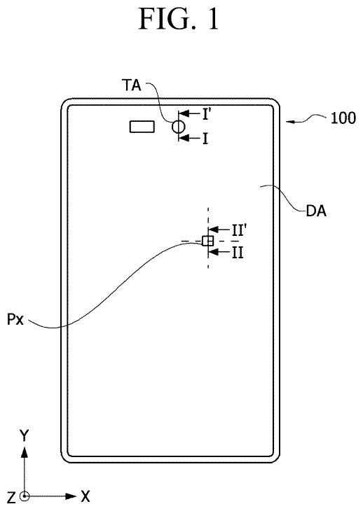

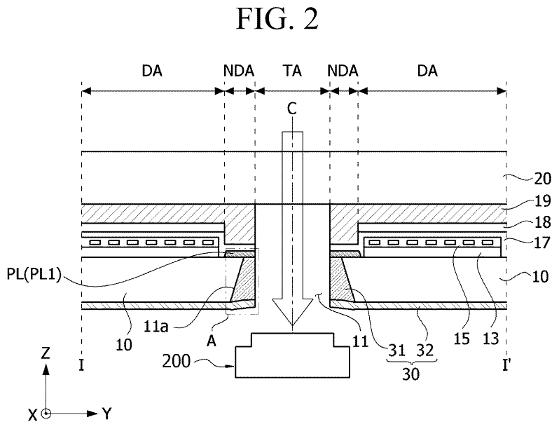

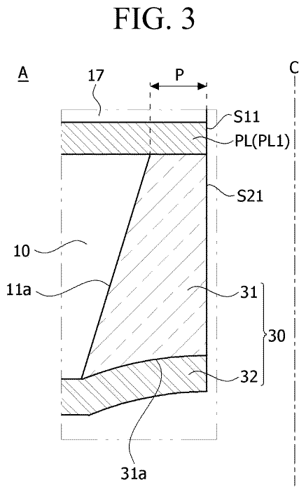

FIG. 1 is a conceptual view of a display device according to an embodiment of the present specification, FIG. 2 is a cross-sectional view taken along line I-I′ in FIG. 1, and FIG. 3 is an enlarged view of a part A in FIG. 2. In FIG. 2, reference numeral C indicating a virtual line may indicate the center of a light-transmissive area TA.

With reference to FIGS. 1 and 2, a display device according to an embodiment of the present specification may include a display panel 100 on which an input image is visually reproduced, and a sensor 200 disposed corresponding to the light-transmissive area TA of the display panel 100. The display panel 100 may include a display area DA where an image is displayed, the light-transmissive area TA where light is incident, and a non-display area NDA formed between the light-transmissive area TA and the display area DA. The light-transmissive area TA may be a hole structure for allowing light to enter the sensor 200 disposed below the display panel 100, but is not necessarily limited thereto. The non-display area NDA may be an area where no image is displayed, unlike the display area DA.

The display panel 100 may be a panel with a rectangular structure having a width in an X-axis direction, a length in a Y-axis direction, and a thickness in a Z-axis direction. The width and length of the display panel 100 may be set to various design values depending on the application field of the display device. The X-axis direction may refer to a width direction, a row direction, or a horizontal direction, the Y-axis direction may refer to a longitudinal direction, a column direction, or a vertical direction, and the Z-axis direction may refer to an up-down direction or a thickness direction. The X-axis direction, the Y-axis direction, and the Z-axis direction may be perpendicular to one another, but may also refer to different directions that are not perpendicular to one another. Accordingly, each of the X-axis direction, the Y-axis direction, and the Z-axis direction may be described as one of a first direction, a second direction, and a third direction. A surface extending in the X-axis direction and the Y-axis direction may refer to a horizontal surface.

In the display area DA of the display panel 100, data lines, gate lines crossing the data lines, and pixels Px arranged in a matrix form defined by the data lines and the gate lines may be disposed. Each of the pixels Px includes subpixels of different colors for color reproduction. The subpixels include a red subpixel, a green subpixel, and a blue subpixel. Although not illustrated, each of the pixels Px may further include a white subpixel. Hereinafter, the pixel may be interpreted as a subpixel unless otherwise defined. Each of the subpixels may include a pixel circuit. The pixel circuit may include a light-emitting element, a driving element that supplies a current to the light-emitting element, one or more switch elements that switch current paths of the driving element and the light-emitting element, a capacitor that maintains a voltage Vgs between a gate and a source of the driving element, and the like.

The light-emitting element may be implemented in an element structure, such as an organic light-emitting diode (OLED) display, a quantum dot display, and a micro light-emitting diode (LED) display. Hereinafter, an OLED structure including an organic compound layer will be described as an example.

An OLED includes an organic compound layer formed between an anode electrode and a cathode electrode. The organic compound layer may include a hole injection layer (HIL), a hole transport layer (HTL), an emission layer (EML), an electron transport layer (ETL), and an electron injection layer (EIL), but is not limited thereto. When a voltage is applied to the anode electrode and the cathode electrode of the OLED, holes passing through the hole transport layer (HTL) and electrons passing through the electron transport layer (ETL) are moved to the emission layer (EML) to form excitons, so that visible light is emitted from the emission layer (EML).

A display panel driver writes pixel data of an input image into the pixels Px. The display panel driver includes a data driver that supplies a data voltage of the pixel data to the data lines, and a gate driver that sequentially supplies a gate pulse to the gate lines. The data driver is integrated into a drive IC. The drive IC may be attached onto the display panel 100.

The drive IC is connected to the data lines through data output channels and supplies a voltage of a data signal to the data lines. The drive IC includes a timing controller. The timing controller transmits pixel data of an input image received from a host system to the data driver, and controls the operation timing of the data driver and the gate driver. The data driver of the drive IC converts pixel data into a gamma compensation voltage through a digital to analog converter (DAC), and outputs a data voltage.

The gate driver may include a shift register formed in a circuit layer of the display panel 100 along with a pixel array. The shift register of the gate driver sequentially supplies a gate signal to the gate lines under the control of the timing controller. The gate signal may include a scan pulse and an emission control pulse (hereinafter, referred to as an “EM pulse”). The shift register may include a scan driver that outputs a scan pulse and an EM driver that outputs an EM pulse.

The host system may be implemented as an application processor (AP). The host system transmits pixel data of an input image to the drive IC. The host system may be connected to the drive IC through, a flexible printed circuit (FPC).

Various wiring and driving circuits may be disposed in the non-display area NDA, and a pad part to which an integrated circuit, a printed circuit, and the like are connected may be disposed.

The flexible printed circuit may be formed on a flexible printed circuit board and may be connected to the drive IC through the pad part. The drive IC may be disposed on the display panel 100, but is not necessarily limited thereto. For example, the drive IC may also be disposed on the flexible printed circuit board.

The display panel 100 may be manufactured based on a glass substrate.

As shown in FIG. 2, the display panel 100 may include a circuit part 13 disposed on a substrate 10 and a light-emitting element part 15 disposed on the circuit part 13. The display panel 100 may include an encapsulation part 17 disposed on the light-emitting element part 15, a polarizer 19 disposed on the encapsulation part 17, and a cover glass 20 disposed on the polarizer 19. The display panel may further include a touch part 18 disposed between the light-emitting element part 15 and the polarizer 19.

The substrate 10 may be made of an insulating material or a material with flexibility. For example, the substrate 10 may be made of glass, metal, or plastic, but is not limited thereto. However, as the substrate 10, a glass substrate having a certain strength may be used for an etching process for process simplification.

The circuit part 13 may include the pixel circuit connected to wirings, such as the data lines, the gate lines, and power lines, the gate driver connected to the gate lines, and the like. Additionally, the wiring and circuit elements of the circuit part 13 may include a plurality of insulating layers, two or more metal layers separated with the insulating layer therebetween, and an active layer including a semiconductor material. The circuit element may include a transistor implemented as a thin film transistor (TFT) and a capacitor.

The light-emitting element part 15 may include light-emitting elements driven by the pixel circuit. The light-emitting elements may include a red light-emitting element, a green light-emitting element, and a blue light-emitting element. In another embodiment, the light-emitting element part 15 may include a white light-emitting element and a color filter. The light-emitting elements of the light-emitting element part 15 may be covered with a protective layer including an organic film.

The light-emitting element part 15 may further include a color filter array disposed on pixels that selectively transmit red, green, and blue wavelengths.

The encapsulation part 17 covers the light-emitting element part 15 to seal the circuit part 13 and the light-emitting element part 15. The encapsulation part 17 may have a multi-insulating film structure in which an organic film and an inorganic film are alternately stacked. The inorganic film may block the penetration of moisture or oxygen. The organic film may planarize the surface of the inorganic film. When the organic film and the inorganic film are stacked in multiple layers, a movement path of moisture or oxygen becomes longer compared to a single layer, so that the penetration of moisture/oxygen affecting the light-emitting element part 15 may be effectively blocked.

The touch part 18 may include capacitive touch sensors that sense a touch input based on a change in capacitance before and after the touch input. The touch part 18 may include metal wiring patterns and insulating films that form the capacitance of the touch sensors. The insulating films may insulate intersection portions of the metal wiring patterns and planarize the surface of the touch part.

The polarizer 19 may be disposed on the light-emitting element part 15. The polarizer 19 may improve the outdoor visibility of the display device. For example, the polarizer 19 may improve visibility and contrast ratio by converting the polarization of external light reflected by metal patterns of the circuit part 13. The polarizer 19 may be implemented as a polarizer or a circular polarizer in which a linear polarizer and a phase retardation film are bonded. The cover glass 20 may be attached onto the polarizer 19.

The light-transmissive area TA may be formed in the display area DA. The non-display area NDA may be disposed to surround the light-transmissive area TA. The non-display area NDA may have a plurality of dam structures to protect the light-emitting elements in the display area DA from moisture, oxygen, or the like that may enter from the light-transmissive area TA.

The light-transmissive area TA may have a through-hole structure for injecting light into the sensor 200, such as a camera, but is not necessarily limited thereto. For example, pixels with low density may be disposed in the light-transmissive area TA.

The substrate 10 may include an opening 11 disposed in the light-transmissive area TA. The opening 11 may have a tapered shape whose width becomes narrower toward the cover glass 20, but is not necessarily limited thereto. For example, the opening 11 may be formed in a tapered shape whose width becomes wider toward the cover glass 20, or may be formed in a cylindrical shape with a constant width. For example, the shape of the opening 11 may be variously changed depending on the type of etching solution and an etching method.

A protective layer PL may be disposed on the opening 11 of the substrate 10.

Accordingly, the opening 11 of the display panel 100 may be provided as a concave groove formed on the back surface of the display panel 100.

The protective layer PL may protect the display panel 100 from a laser emitted to the display panel 100. For example, the display panel 100 may be irradiated with a laser to facilitate etching in some areas of the substrate 10, and the protective layer PL may prevent the display panel 100 from being damaged by the laser. Accordingly, the protective layer PL may include at least one of an organic insulating layer made of an organic material, an inorganic insulating layer made of an inorganic material, and a metal layer made of a metal material. Due to the arrangement with the substrate 10, the protective layer PL may include an upper protective layer and a lower protective layer.

The protective layer PL may prevent an etching solution from penetrating into the interior of the display panel 100 when the substrate 10 is etched. Accordingly, the protective layer PL may be referred to as an anti-etching layer.

The protective layer PL may include an organic material resistant to etching solutions. For example, the protective layer PL may include one selected from the group consisting of polyester-based polymers, silicone-based polymers, acrylic polymers, polyolefin-based polymers, and copolymers thereof. However, the protective layer PL is not necessarily limited thereto, and may include various materials, such as inorganic materials or metal materials resistant to etching solutions.

The protective layer PL may be formed by extending from at least one of layers constituting the circuit part 13, the light-emitting element part 15, the encapsulation part 17, and the touch part 18. Alternatively, the protective layer PL may be formed in a process of forming at least one of the layers constituting the circuit part 13, the light-emitting element part 15, the encapsulation part 17, and the touch part 18 in consideration of process efficiency. For example, the protective layer PL may be a dummy layer of the circuit part 13, the light-emitting element part 15, the encapsulation part 17, and the touch part 18. With such a configuration, the protective layer PL may be formed without adding a separate process.

According to an embodiment, the protective layer PL may include a protrusion P protruding toward the light-transmissive area TA. The protrusion P may be a portion that protrudes from an upper surface of the opening 11 toward a center C of the light-transmissive area TA. Such a protrusion P may be formed in a process of cutting the protective layer PL by a laser.

A coating layer 30 may be formed on the back surface of the substrate 10. The coating layer 30 may be made of an organic material including a polyester-based polymer or an acrylic-based polymer. The coating layer 30 may include a side coating layer 31 formed on an inner side surface of the opening 11 and a back coating layer 32 disposed under the substrate 10.

A lower surface 31a of the side coating layer 31 may be concavely formed toward the anti-etching layer. However, the side coating layer 31 is not necessarily limited thereto and may not shrink depending on a material. Accordingly, the lower surface 31a of the side coating layer 31 may be substantially flat even after curing is completed.

An inclined surface 11a of the opening 11 and a side surface S11 of the protrusion P of the protective layer PL may have different slopes. With reference to FIG. 3, because the opening 11 is etched by an etching solution to have a tapered shape but the protective layer PL is cut by a laser to form a relatively vertical cross-section, an inclination angle of the side surface S11 of the protrusion P may be greater than an inclination angle of the inclined surface 11a.

A side surface S21 of the coating layer 30 disposed below the protrusion P may have the same inclination angle as the side surface S11 of the protrusion P, but is not necessarily limited thereto. For example, the side surface S21 of the coating layer 30 may be formed at the same inclination angle as the inclined surface 11a.

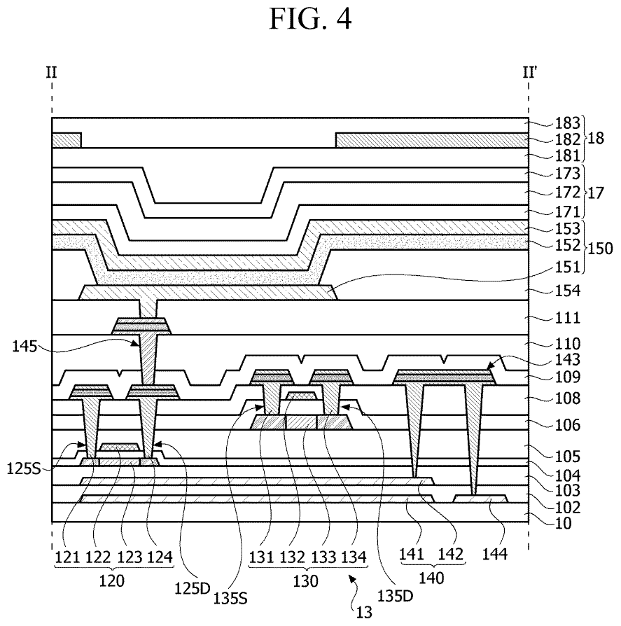

FIG. 4 is a cross-sectional view taken along line II-IT′ in FIG. 1.

As shown in FIG. 4, a first transistor 120 and a second transistor 130 may be disposed on the substrate 10 in the display area DA, and the light-emitting element 150 may be disposed on a second planarization layer 111.

A first light blocking layer 141 and a metal layer 144 may be disposed on the substrate 10. The first light blocking layer 141 may include molybdenum and/or aluminum. The first light blocking layer 141 may block light entering a first semiconductor layer 123 or a second semiconductor layer 133. The first light blocking layer 141 may overlap a first semiconductor layer 123 or a second semiconductor layer 133 in the Z direction. The metal layer 144 may be spaced apart from the first light blocking layer 141, and may be formed together with the first light blocking layer 141 in a formation process of the first light blocking layer 141.

A multi-buffer layer 102 may delay the diffusion of moisture or oxygen penetrating into the substrate 10, and may be formed by alternately stacking silicon nitride (SiNₓ) and silicon oxide (SiOₓ) at least once. A second light blocking layer 142 may be disposed on the multi-buffer layer 102. The second light blocking layer 142 may include molybdenum and/or aluminum. The second light blocking layer 142 may block light entering the first semiconductor layer 123 or the second semiconductor layer 133. The second light blocking layer 142 may overlap the first light blocking layer 141 in the Z direction, and may more effectively block light entering the first semiconductor layer 123 or the second semiconductor layer 133.

An active buffer layer 103 may perform a function of protecting the first semiconductor layer 123 and blocking various types of defects entering from the substrate 10. The active buffer layer 103 may be made of amorphous silicon (a-Si), silicon nitride (SiNₓ), silicon oxide (SiOₓ), or the like. The first semiconductor layer 123 of the first transistor 120 may be made of a polycrystalline semiconductor layer, and may include a channel region, a source region, and a drain region.

The polycrystalline semiconductor layer has higher mobility than an amorphous semiconductor layer and an oxide semiconductor layer, resulting in low energy consumption and excellent reliability. Due to these advantages, the polycrystalline semiconductor layer may be used in a driving transistor.

A first gate electrode 122 may be disposed on a lower gate insulating layer 104 and may overlap the first semiconductor layer 123.

The second transistor 130 may be disposed on a lower interlayer dielectric layer 105. An upper gate insulating layer 106 may be disposed on the second semiconductor layer 133 to insulate the second gate electrode 132 from the second semiconductor layer 133.

An upper interlayer dielectric layer 108 may be disposed on the second gate electrode 132. The first gate electrode 122 and the second gate electrode 132 may each be a single layer or a multilayer including any one of molybdenum (Mo), aluminum (Al), chromium (Cr), gold (Au), titanium (Ti), nickel (Ni), neodymium (Nd), and copper (Cu), or an alloy thereof, but is not limited thereto.

The lower interlayer dielectric layer 105 may be made of an inorganic insulating layer with a higher hydrogen particle content than the upper interlayer dielectric layer 108. For example, the lower interlayer dielectric layer 105 may be made of silicon nitride (SiNₓ) formed through a deposition process using NH₃ gas, and the upper interlayer dielectric layer 108 may be made of silicon oxide (SiOₓ). The hydrogen particles included in the lower interlayer dielectric layer 105 may be diffused into the polycrystalline semiconductor layer during a hydrogenation process and may fill voids in the polycrystalline semiconductor layer with hydrogen. Accordingly, the polycrystalline semiconductor layer may be stabilized, thereby preventing deterioration in the characteristics of the first transistor 120.

After the activation and hydrogenation process of the first semiconductor layer 123 of the first transistor 120, the second semiconductor layer 133 of the second transistor 130 may be formed. In such a case, the second semiconductor layer 133 may be made of an oxide semiconductor. Because the second semiconductor layer 133 is not exposed to the high temperature atmosphere of the activation and hydrogenation process of the first semiconductor layer 123, damage to the second semiconductor layer 133 may be prevented and reliability may be improved.

After the upper interlayer dielectric layer 108 is disposed, a first source contact hole 125S and a first drain contact hole 125D may be formed to correspond to source and drain regions of the first transistor 120, respectively, and a second source contact hole 135S and a second drain contact hole 135d may be formed to correspond to source and drain regions of the second transistor 130, respectively.

The first source contact hole 125S and the first drain contact hole 125D may be holes formed continuously from the upper interlayer dielectric layer 108 to the lower gate insulating layer 104. Also in the second transistor 130, the second source contact hole 135S and the second drain contact hole 135D may be holes formed continuously from the upper interlayer dielectric layer 108 to the upper gate insulating layer 106.

A first source electrode 121 and a first drain electrode 124 corresponding to the first transistor 120 and a second source electrode 131 and a second drain electrode 134 corresponding to the second transistor 130 may be formed simultaneously. Through this, the number of processes for forming the source and drain electrodes of each of the first transistor 120 and the second transistor 130 may be reduced.

The first source and drain electrodes 121 and 124 and the second source and drain electrodes 131 and 134 may each be a single layer or a multilayer made of any one of molybdenum (Mo), aluminum (Al), chromium (Cr), gold (Au), titanium (Ti), nickel (Ni), neodymium (Nd), and copper (Cu), or an alloy thereof, but is not limited thereto.

The first source and drain electrodes 121 and 124 and the second source and drain electrodes 131 and 134 may each have a three-layer structure. For example, the first source electrode 121 may include a first electrode layer made of Ti, a second electrode layer made of Al, and a third electrode layer made of Ti, and the other source and drain electrodes may have the same structure.

A storage capacitor 140 may be disposed between the first transistor 120 and the second transistor 130. According to an embodiment, the storage capacitor 140 may be formed using the first light blocking layer 141 and the second light blocking layer 142. For example, the second light blocking layer 142 may be electrically connected to the pixel circuit through a storage supply line 143. However, the structure of the storage capacitor 140 is not necessarily limited thereto and may be variously modified using two different metal layers. The storage supply line 143 may be made of the same material on the same plane as the first source and drain electrodes 121 and 124 and the second source and drain electrodes 131 and 134, so that that the storage supply line 143 may be formed simultaneously with the first source and drain electrodes 121 and 124 and the second source and drain electrodes 131 and 134 by using the same mask process.

An inorganic insulating material, such as SiNₓ or SiOₓ, is deposited on the entire surface of the substrate 10 on which the first source and drain electrodes 121 and 124, the second source and drain electrodes 131 and 134, and the storage supply line 143 are formed, so that a protective film 109 may be formed.

A first planarization layer 110 may be formed on the protective film 109. For example, by coating an organic insulating material, such as acrylic resin, on the entire surface of the protective film 109, the first planarization layer 110 may be disposed.

After the protective film 109 and the first planarization layer 110 are disposed, a contact hole exposing the first source electrode 121 or the first drain electrode 124 of the first transistor 120 may be formed through a photolithography process. A connection electrode 145 may be disposed in the contact hole exposing the first drain electrode 124 by using a material made of Mo, Ti, Cu, AlNd, Al, and Cr, or an alloy thereof.

A second planarization layer 111 may be disposed on the connection electrode 145, and a contact hole exposing the connection electrode 145 may be formed in the second planarization layer 111, so that the light-emitting element 150 connected to the first transistor 120 may be disposed. The connection electrode 145 may be formed as a structure with a plurality of layers, like the first source and drain electrodes 121 and 124.

The light-emitting element 150 may include an anode electrode 151 connected to the first drain electrode 124 of the first transistor 120, at least one emission stack 152 formed on the anode electrode 151, and a cathode electrode 153 formed on the emission stack 152. The emission stack 152 may include a hole injection layer, a hole transport layer, an emission layer, an electron transport layer, and an electron injection layer. In a tandem structure in which a plurality of emission layers overlap each other, a charge generation layer may be additionally disposed between the emission layers. The emission layers may emit different colors for each subpixel.

The anode electrode 151 may be connected to the connection electrode 145 exposed through the contact hole penetrating the second planarization layer 111. The anode electrode 151 may be formed in a multi-layer structure including a transparent conductive film and an opaque conductive film with high reflection efficiency. The transparent conductive film may be made of a material with a relatively high work function value, such as indium-tin-oxide (ITO) or indium-zinc-oxide (IZO), and the opaque conductive film may have a single-layer or multi-layer structure including Al, Ag, Cu, Pb, Mo, Ti, or an alloy thereof.

For example, the anode electrode 151 may be formed in a structure in which a transparent conductive film, an opaque conductive film, and a transparent conductive film are sequentially stacked, or in a structure in which a transparent conductive film and an opaque conductive film are sequentially stacked.

The anode electrode 151 is disposed on the second planarization layer 111 to overlap not only an emission area provided by a bank 154 but also a pixel circuit area where the first and second transistors 120 and 130 and the storage capacitor 140 are disposed, so that an emission area may be increased.

The emission stack 152 may be formed by stacking a hole transport layer, an organic emission layer, and an electron transport layer on the anode electrode 151 in that order or in the reverse order. In addition, the emission stack 152 may further include a charge generation layer and include first and second emission stacks facing each other with the charge generation layer therebetween.

The bank 154 may be formed to expose the anode electrode 151. Such a bank 154 may be made of an organic material, such as photo acryl, and may be a translucent material, but is not limited thereto and may be made of an opaque material to prevent light interference between subpixels.

The cathode electrode 153 may be formed on an upper surface of the emission stack 152 to face the anode electrode 151 with the emission stack 152 interposed therebetween. When the cathode electrode 153 is applied to a top-emission organic light-emitting display device, the cathode electrode 153 may be formed by a transparent conductive film in which indium-tin-oxide (ITO), indium-zinc-oxide (IZO), or magnesium-silver (Mg—Ag) is thinly formed.

The encapsulation part 17 may be formed on the cathode electrode 153 to protect the light-emitting element 150. Because the light-emitting element 150 may react with external moisture or oxygen due to the organic nature of the emission stack 152 to cause dark-spots or pixel shrinkage, the encapsulation part 17 may be disposed on the cathode electrode 153 to prevent such a problem.

The encapsulation part 17 may include a first encapsulation layer 171, a foreign matter compensation layer 172, and a second encapsulation layer 173. The first encapsulation layer 171 and the second encapsulation layer 173 may each be made of an inorganic insulating material, and the foreign matter compensation layer 172 may be made of an organic insulating material.

The touch part 18 may be disposed on the encapsulation part 17. The touch part 18 may include a first touch planarization layer 181, a touch electrode 182, and a second touch planarization layer 183. The first touch planarization layer 181 and the second touch planarization layer 183 may be disposed to eliminate a step at the point where the touch electrode 182 is disposed and to ensure good electrical insulation.

According to embodiments, the first transistor 120 made of low-temperature polycrystalline silicon and the second transistor 130 made of oxide semiconductor are disposed in different layers, so that a thin film transistor (TFT) having different driving characteristics may be disposed in the display device. However, it is not necessarily limited thereto, and only thin film transistors having the same driving characteristics may be used or thin film transistors having various circuit structures may be used.

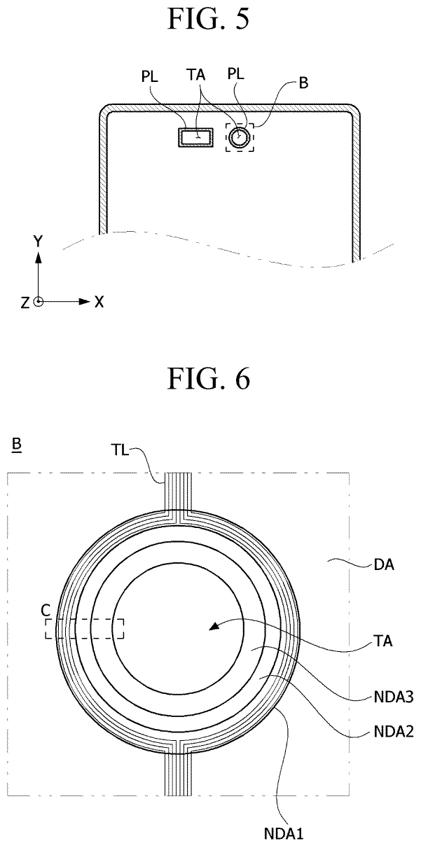

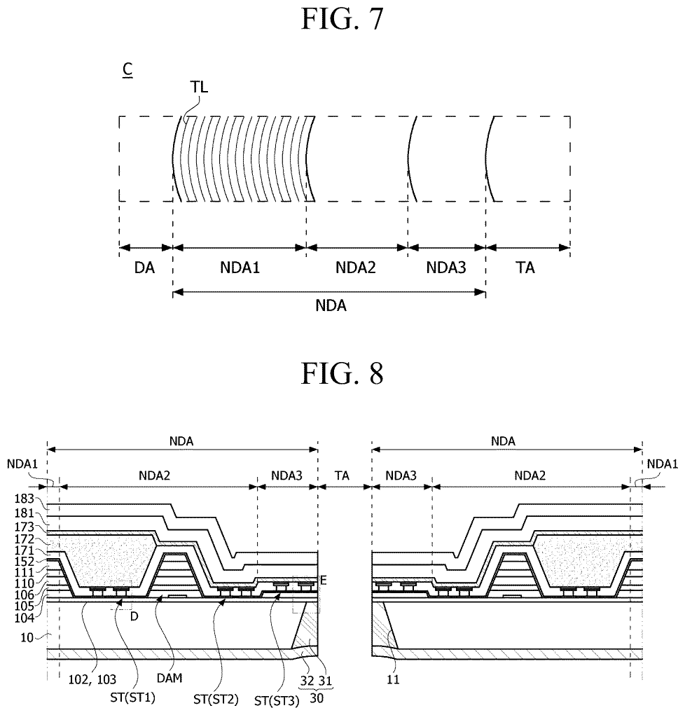

FIG. 5 is a view illustrating the light-transmissive area and the protective layer surrounding an edge area of the light-transmissive area, FIG. 6 is an enlarged view illustrating an area B in FIG. 5, and FIG. 7 is an enlarged view illustrating an area C in FIG. 6.

With reference to FIG. 5, the protective layer PL may be disposed to entirely surround the periphery, for example, the edge, of the light-transmissive area TA. The protective layer PL may be disposed to entirely surround the edge of the light-transmissive area TA, so that when a laser is emitted for etching, the protective layer PL may protect wirings arranged in the Z-axis direction may be protected from the laser. In such a case, various structures for preventing the penetration of moisture, oxygen, or the like may be disposed in the non-display area NDA, and such structures may also be protected from a laser or an etching solution by the protective layer PL. For example, before the formation of the opening 11 provided as a through hole on the inside of a mother substrate through etching, a laser may be emitted to an area where the opening 11 is formed, and the protective layer PL may be disposed in the laser emission direction to prevent damage to wirings or the like caused by the laser.

When the opening 11 is formed through an etching process, the protective layer PL may serve as an anti-etching layer to prevent an etching solution from penetrating into the interior of the display panel 100. For example, the protective layer PL may overlap the opening 11 in the Z-axis direction to prevent the etching solution from penetrating into the interior of the display panel 100.

Before a laser cutting process, the protective layer PL may be disposed in the light-transmissive area TA and the non-display area NDA located around the light-transmissive area TA, thereby protecting the display panel 100 from a laser and preventing an etching solution from penetrating into the interior of the display panel 100.

Moreover, because the display device according to an embodiment of the present specification may form various shapes of openings 11 in the substrate 10 made of glass by etching, there is an advantage that it is possible to form various openings while maintaining the rigidity of the substrate 10 compared to scribing, breaking, and grinding techniques in the related art. In addition, the display device according to an embodiment of the present specification has the advantage of enabling process optimization because the opening 11 may be formed along with side processing for forming a notch or rounding on the side of the substrate 10. In such a case, it is of course that the protective layer PL may be formed on the side of the substrate 10.

With reference to FIGS. 6 and 7, the light-transmissive area TA where various sensors are disposed may be formed in a circular shape and the non-display area NDA may be disposed around the light-transmissive area TA, but the present specification is not necessarily limited thereto. For example, the light-transmissive area TA may have various shapes, such as a polygon or an oval, and the shape of the non-display area NDA may also vary depending on the shape of the light-transmissive area TA.

The non-display area NDA may include a wiring area NDA1 where a wiring TL that bypasses the light-transmissive area TA is disposed, a moisture penetration prevention area NDA2 disposed between the wiring area NDA1 and the light-transmissive area TA, and a dummy area NDA3 where the protective layer PL is disposed. The moisture penetration prevention area NDA2 and the dummy area NDA3 may be disposed to surround the light-transmissive area TA, and the dummy area NDA3 may be disposed adjacent to the light-transmissive area TA. In such a case, the dummy area NDA3 may also play a role in preventing moisture penetration.

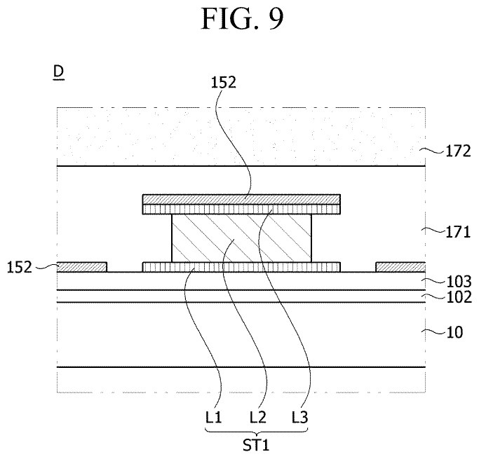

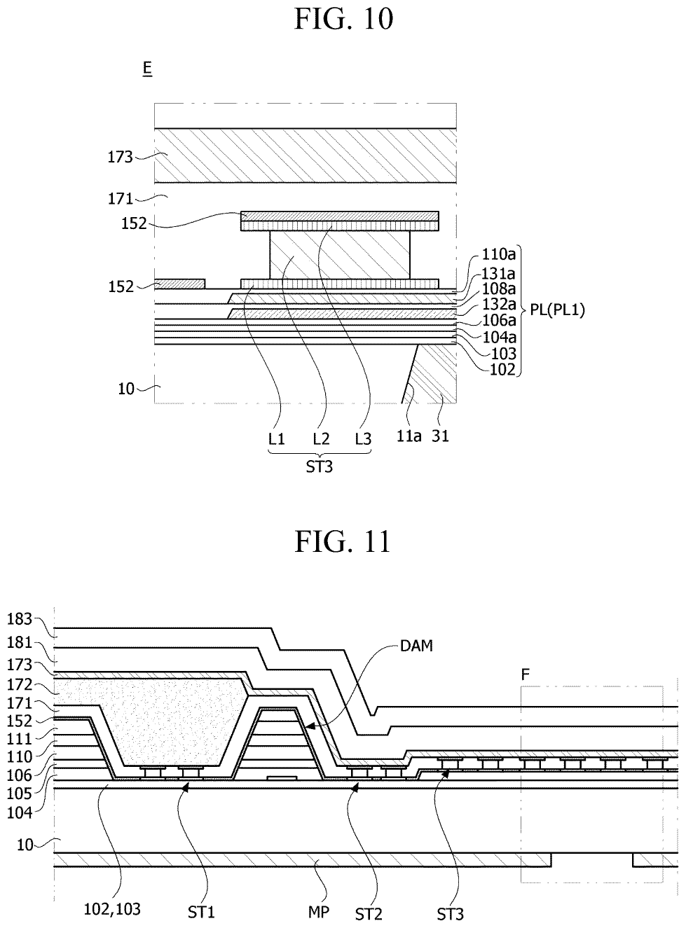

FIG. 8 is a view illustrating a display device according to an embodiment of the present specification, FIG. 9 is an enlarged view illustrating an area D in FIG. 8, and FIG. 10 is an enlarged view illustrating an area E in FIG. 8.

As illustrated in FIG. 8, the moisture penetration prevention area NDA2 may include a dam DAM and a plurality of protruding patterns ST. The dam DAM and the plurality of protruding patterns ST may be formed using a plurality of layers disposed in the display area DA or a plurality of layers extending from the display area DA. In such a case, the number of dams DAM and the number of protruding patterns ST are not particularly limited. The dam DAM may be disposed on a buffer layer 101, and the buffer layer 101 may be an inorganic insulating layer. The buffer layer 101 may be formed using at least one of a multi-buffer layer 102 and an active buffer layer 103.

The dam DAM and the protruding pattern ST may be disposed in a closed loop shape surrounding the light-transmissive area TA, thereby preventing moisture or the like from penetrating into the display area DA through the light-transmissive area TA. In such a case, a width of the moisture penetration prevention area NDA2 may have a predetermined length to prevent moisture penetration.

The dummy area NDA3 may be an area formed for a margin when the substrate 10 is etched and/or cut by a laser. For example, when there is no dummy area NDA3, the moisture penetration prevention area NDA2 may be damaged during laser cutting, making it vulnerable to moisture penetration, and a minimum layer may be disposed on the substrate 10 in the dummy area NDA3 to facilitate laser cutting. In addition, the substrate 10 or the like may be damaged by a laser, and the dummy area NDA3 may be disposed to cope with such damage.

The protective layer PL disposed in the dummy area NDA3 may prevent an etching solution from penetrating into the interior of the display panel 100 when the substrate 10 is etched, and prevent damage caused by a laser emitted before etching. The protective layer PL may include at least one of an inorganic insulating layer, an organic insulating layer, and a metal layer. In such a case, the metal layer may include molybdenum (Mo) having strong corrosion resistance to an etching solution.

The plurality of protruding patterns ST may be disposed in the non-display area NDA. The protruding pattern ST may be formed to have an undercut shape so that a width of the protruding pattern ST has a width proximal to the upper protective layer PL1 is less than a width of the protruding pattern ST distal to the upper protective layer PL1. The protruding pattern ST may disconnect the emission stack 152 formed on the non-display area NDA.

The plurality of protruding patterns ST may include a plurality of first protruding patterns ST1 and a plurality of second protruding patterns ST2 disposed in the moisture penetration prevention area NDA2, and a plurality of third protruding patterns ST3 disposed in the dummy area NDA3.

The plurality of first protruding patterns ST1 may be disposed between the display area DA and the dam DAM, and the plurality of second protruding patterns ST2 may be disposed between the dam DAM and the dummy area NDA3. The third protruding pattern ST3 may be disposed on the protective layer PL in the dummy area NDA3. Accordingly, the protective layer PL may protect the third protruding pattern ST3 from a laser emitted before an etching process.

The shapes of the plurality of first protruding patterns ST1, second protruding patterns ST2, and third protruding patterns ST3 may all be the same, but are not necessarily limited thereto. For example, the first protruding pattern ST1 and the second protruding pattern ST2 may have the same shape, but the third protruding pattern ST3 may have a different shape. For example, because the third protruding pattern ST3 is disposed adjacent to the light-transmissive area TA formed by laser cutting, the third protruding pattern ST3 may have a shape different from that of the first protruding pattern ST1 in consideration of shocks generated during laser cutting. The protruding patterns ST1, ST2, and ST3 may be variously modified to have a structure capable of disconnecting the emission stack 152.

The opening 11 may be formed in the substrate 10 to correspond to the light-transmissive area TA. The opening 11 may have a larger diameter than the light-transmissive area TA.

The side coating layer 31 may be formed on the side surface of the opening 11. The side coating layer 31 may cover the side surface of the opening 11. The protective layer PL may be disposed on the side coating layer 31.

The side coating layer 31 may be made of an organic material that absorbs light. For example, the side coating layer 31 may include an organic material having an optical density (OD) of 1.0 or more.

The back coating layer 32 may be disposed under the substrate 10 and under the side coating layer 31. The back coating layer 32 may extend further from the back surface of the substrate 10 and be formed up to the side coating layer 31.

The display device according to an embodiment of the present specification may improve the adhesion of the back coating layer 32 by forming the back coating layer 32 to cover the side coating layer 31. In such a case, the back coating layer 32 may be formed only on the back surface of the substrate 10 to protect the substrate 10. However, because the back coating layer 32 made of an organic material has a relatively low adhesion with the substrate 10, it may be peeled off from the substrate 10 due to external environment or impact. Accordingly, the adhesion of the back coating layer 32 may be improved by bonding the back coating layer 32 to the side coating layer 31 made of an organic material at the opening 11 of the substrate 10. Through this, the back coating layer 32 may be prevented from being peeled off from the substrate 10.

According to an embodiment, the side surface of the light-transmissive area TA may be formed vertically. For example, the side surface of the back coating layer 32, the side surface of the side coating layer 31, the side surface of the protective layer PL, and the side surface of the polarizer 19, which form the side surface of the light-transmissive area TA, may be cut with a laser to have the same vertical plane.

With reference to FIG. 9, the plurality of protruding patterns ST may include a first pattern layer L1, a second pattern layer L2, and a third pattern layer L3 sequentially stacked. The first pattern layer L1 and the third pattern layer L3 may each include a titanium (Ti) material, and the second pattern layer L2 may include an aluminum (Al) material.

The protruding pattern ST according to an embodiment may be made of the same material as the source/drain electrodes 121 and 124 or the connection electrode 145 in the display area DA. For example, the plurality of protruding patterns ST may be formed simultaneously when the connection electrode 145 is formed and then etched to be separated into a plurality of protruding patterns. In such a case, the second pattern layer L2 made of aluminum may be relatively more etched due to the difference in an etching reaction speed. Accordingly, because a width of the second pattern layer L2 may be smaller than a width of the third pattern layer L3, the protruding pattern ST may have an undercut shape. Due to such an undercut shape, the emission stack 152 formed on the plurality of protruding patterns ST may not be continuously formed and may be disconnected between the plurality of protruding patterns ST. Accordingly, the protruding pattern ST may increase a length of a moisture penetration path and simultaneously induce disconnection of the emission stack 152 to block moisture penetration.

The plurality of protruding patterns ST may further prevent peeling of an inorganic insulating layer additionally disposed thereon. The inorganic insulating layer may be relatively easily peeled off during laser cutting, external impact, or the like. However, according to an embodiment, because the inorganic insulating layer is filled between the plurality of protruding patterns ST each having an undercut shape, peeling of the inorganic insulating layer may be prevented. Accordingly, the inorganic insulating layer filled between the plurality of protruding patterns ST may more effectively prevent moisture from penetrating. The inorganic insulating layer may be formed by extending the first encapsulation layer 171 of the encapsulation part 17 disposed in the display area DA. In such a case, the foreign matter compensation layer 172 may be disposed in contact with the first encapsulation layer 171 covering the first protruding pattern ST1, unlike the second protruding pattern ST2. The inorganic insulating layer may also be disposed to cover the plurality of protruding patterns ST.

As shown in FIG. 10, the plurality of third protruding patterns ST3 may be disposed on the protective layer PL. Among the plurality of third protruding patterns ST3, the outermost third protruding pattern ST3 may protrude further into the light-transmissive area TA than the inclined surface 11a of the opening 11 of the substrate 10. However, it is not necessarily limited thereto, and the inclined surface 11a of the opening 11 of the substrate 10 may protrude further into the light-transmissive area TA than the outermost third protruding pattern ST3 among the plurality of third protruding patterns ST3. In such a case, the inorganic insulating layer disposed between the plurality of protruding patterns ST is disposed to be exposed to the light-transmissive area TA, so that the third protruding pattern ST3 may not be exposed through the light-transmissive area TA.

The emission stack 152 formed on the plurality of third protruding patterns ST3 is not continuously formed by the third protruding patterns ST3. Accordingly, the emission stack 152 may be disconnected between the plurality of third protruding patterns ST3. Accordingly, the third protruding pattern ST3 may block a moisture penetration path.

According to an embodiment, because the plurality of third protruding patterns ST3 are formed in the dummy area NDA3 and the inorganic insulating layer is filled between the plurality of protruding patterns ST, peeling of the inorganic insulating layer may be prevented during laser cutting or external impact.

The plurality of third protruding patterns ST3 may also be directly formed on the protective layer PL or may also be disposed on a dummy layer disposed on the protective layer PL. The second encapsulation layer 173 may be disposed in contact with the first encapsulation layer 171 serving as an inorganic insulating layer.

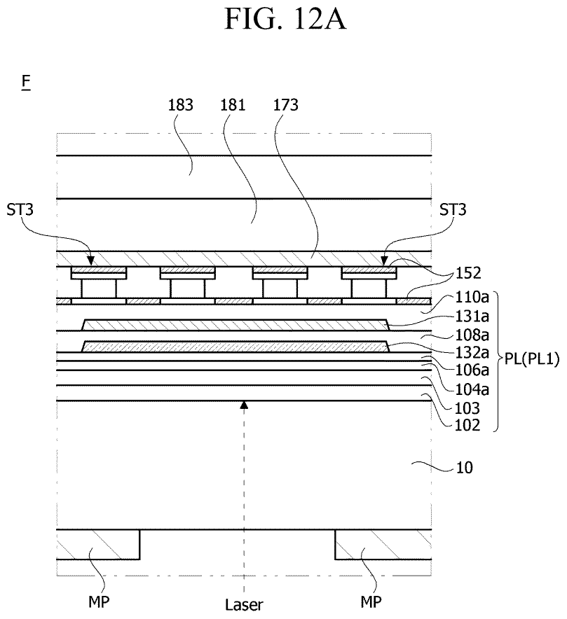

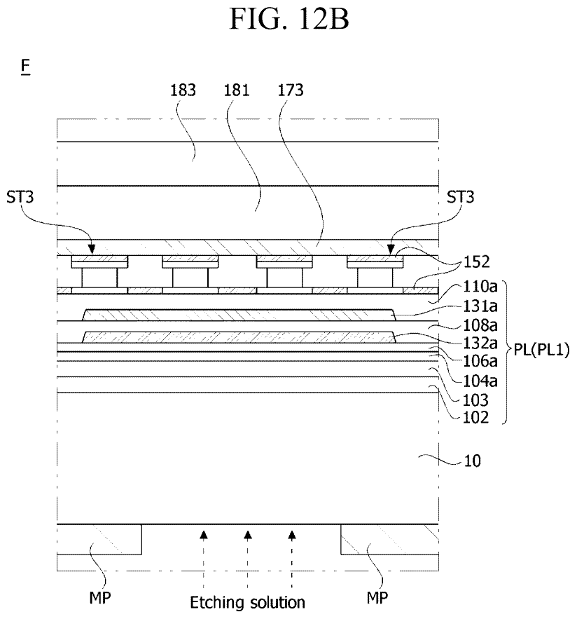

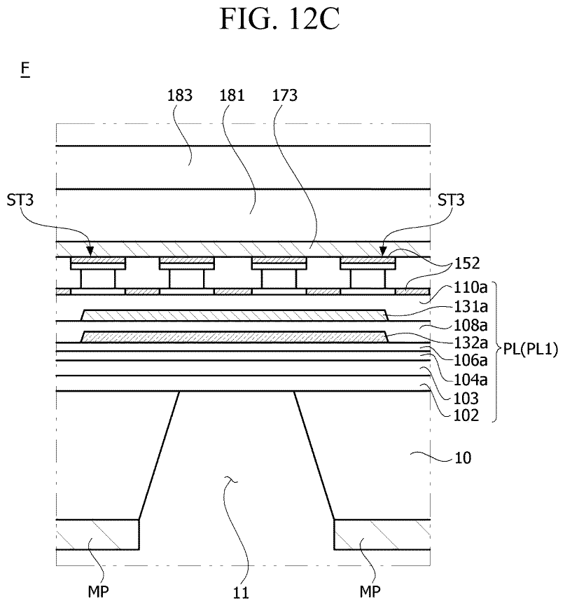

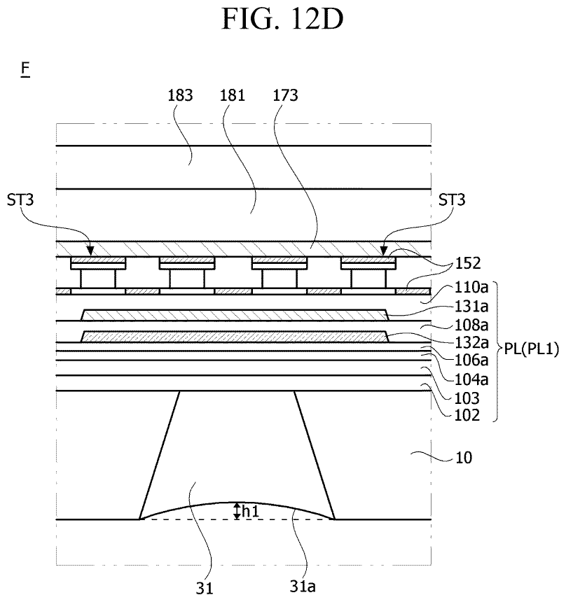

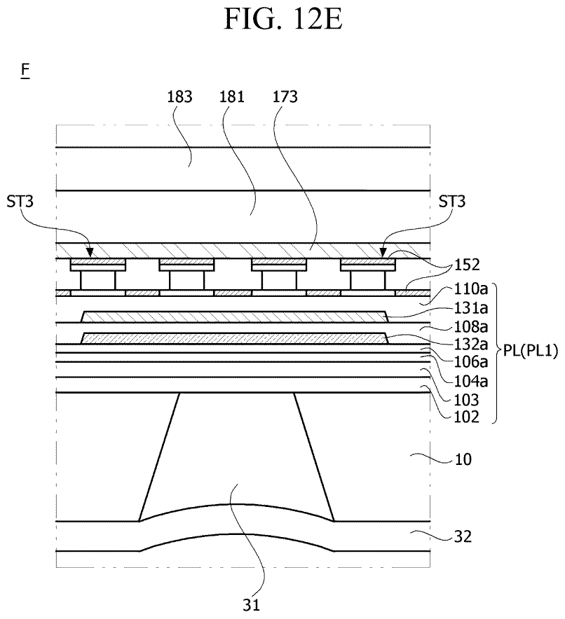

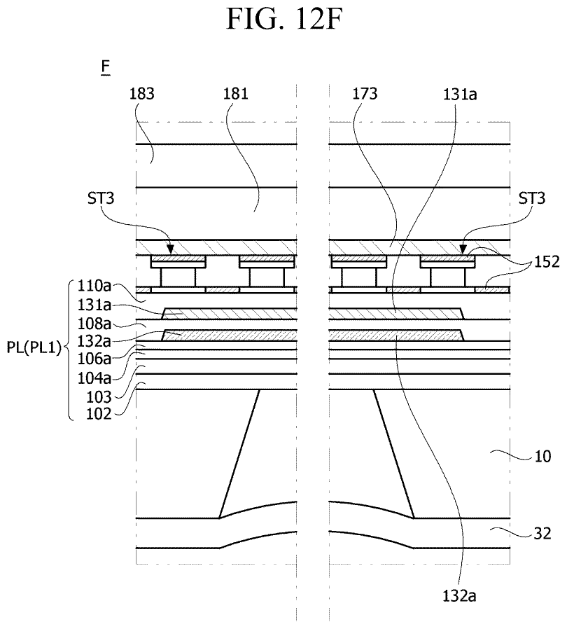

FIG. 11 is a view illustrating the display panel before the light-transmissive area is formed, and FIGS. 12A to 12F are views illustrating a process of etching the substrate to form the light-transmissive area in the display panel, and is a view based on an area F in FIG. 11.

FIG. 12A is a view illustrating a step of irradiating the substrate with a laser.

With reference to FIGS. 11 and 12A, a laser may be emitted to a preset position on the substrate 10 to facilitate etching of the substrate 10 using an etching solution. The preset position may be a position where the light-transmissive area TA is to be formed or a position where the opening 11 of the substrate 10 is to be formed.

FIG. 12B is a view illustrating a step of disposing a mask pattern on the back surface of the substrate.

With reference to FIG. 12B, a mask pattern MP may be formed under the substrate 10. According to an embodiment, the mask pattern MP may be formed according to the number and shape of openings to be formed in the substrate 10 and exposed to an etching solution to simultaneously form a plurality of openings. The formation of the openings and panel-based separation from the mother substrate may be simultaneously performed.

As illustrated in FIGS. 12A and 12B, in the display device according to an embodiment of the present specification, the substrate 10 is irradiated with a laser and then the mask pattern MP is disposed; however, the present specification is not necessarily limited thereto. For example, a laser may be emitted after the mask pattern MP is disposed on the substrate 10.

FIG. 12C is a view illustrating a step of forming the opening on the back surface of the substrate through an etching process.

As shown in FIG. 12C, when an etching solution is brought into contact with an exposed area of the substrate 10, a partial area of the substrate 10 exposed between the mask patterns MP may be etched to form the opening 11. In such a case, the buffer layer 101 formed on the etched substrate 10 may prevent the etching solution from penetrating into the interior of the display panel 100. The buffer layer 101 may be made of an inorganic insulating material, and may be formed of at least one of the multi-buffer layer 102 and the active buffer layer 103 extending from the display area DA in consideration of process optimization; however, the present specification is not necessarily limited thereto. For example, the buffer layer 101 may be formed using a separate inorganic insulating material different from that of the multi-buffer layer 102 and the active buffer layer 103 in the display area DA.

A part of the buffer layer 101 may also be etched. For example, a groove partially etched in the Z-axis direction by an etching solution may be formed in the buffer layer 101, or a hole may be formed entirely through the buffer layer 101. Even when a hole is formed in the buffer layer 101, a planarization layer 110a disposed on the buffer layer 101 may prevent the etching solution from penetrating into the interior of the display panel 100. The planarization layer 110a may be formed together when the first planarization layer 110 or the second planarization layer 111 in the display area DA is formed, thereby implementing process optimization.

FIG. 12D is a view illustrating a step of disposing the side coating layer in the opening.

As shown in FIG. 12D, the opening 11 of the substrate 10 may be filled with the side coating layer 31. Subsequently, when the side coating layer 31 is cured, the side coating layer 31 shrinks by a certain height h1 and a curvature may be formed on the lower surface 31a of the side coating layer 31. However, the side coating layer 31 may not shrink depending on a material.

FIG. 12E is a view illustrating a step of disposing the back coating layer.

With reference to FIG. 12E, the back coating layer 32 may be entirely formed on the back surface of the substrate 10 and the back surface of the side coating layer 31. However, the present specification is not necessarily limited thereto, and the back coating layer 32 may be formed only on the back surface of the substrate 10.

FIG. 12F is a view illustrating a laser cutting step.

As shown in FIG. 12F, the light-transmissive area TA may be formed by irradiating the opening 11 side of the substrate 10 with a laser. In such a case, the protective layer PL and the third protruding pattern ST3 disposed on the substrate 10 may be cut by the laser. According to an embodiment, because a contact area between the protruding pattern ST and the inorganic insulating layer, such as the first encapsulation layer 171, increases, the peeling of the inorganic insulating layer due to laser emission may be prevented.

Because the protective layer PL according to an embodiment of the present specification may include at least one of an organic insulating layer, an inorganic insulating layer, and a metal layer and may include an upper protective layer and a lower protective layer depending on a placement position, the protective layer PL may be provided in various embodiments in response a laser emitted before an etching process.

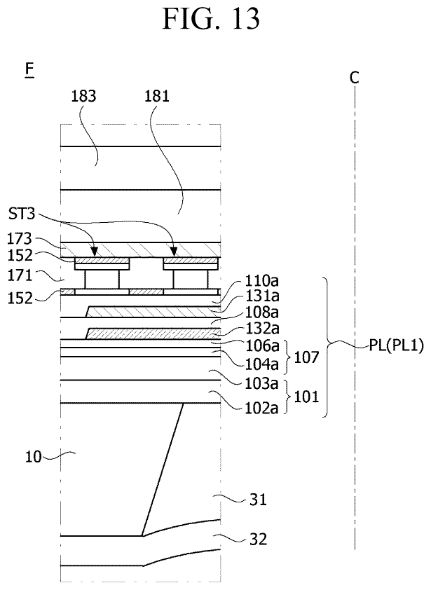

FIG. 13 is a view illustrating an example of a protective layer disposed in the display device according to an embodiment of the present specification. An upper protective layer PL1 illustrated in FIG. 13 may represent a protective layer PL according to a first example.

With reference to FIG. 13, the display device according to an embodiment of the present specification may include the substrate 10, the upper protective layer PL1 disposed on the substrate 10, and the third protruding pattern ST3 disposed on the upper protective layer PL1. Subsequently, the opening 11 may be formed in the substrate 10 and the side coating layer 31 may be disposed in the opening 11. Subsequently, the back coating layer 32 may be disposed on the back surface of the substrate 10.

The upper protective layer PL1 may be disposed on the substrate 10 and may protect components, such as the third protruding pattern ST3, disposed on the upper protective layer PL1 from a laser emitted before an etching process. The upper protective layer PL1 may be disposed on the substrate 10 to prevent an etching solution from penetrating into the interior of the display panel 100. To easily perform the etching process on the substrate 10, the laser emitted before the etching process may be an infrared laser. In such a case, when an infrared laser having a wavelength of 1064 nm is emitted to the substrate 10, the upper protective layer PL1 may effectively protect the third protruding pattern ST3 against the infrared laser in the order of a metal layer, an inorganic insulating layer, and an organic insulating layer.

The upper protective layer PL1 may include the buffer layer 101 disposed on the substrate 10, the planarization layer 110a disposed below the third protruding pattern ST3, and an inorganic insulating layer and a metal layer disposed between the buffer layer 101 and the planarization layer 110a. The inorganic insulating layer and the metal layer may include a first inorganic insulating layer 107 disposed on the buffer layer 101, a first metal layer 132a disposed on the first inorganic insulating layer 107, a second inorganic insulating layer 108a disposed on the first inorganic insulating layer 107 to cover the first metal layer 132a, and a second metal layer 131a disposed on the second inorganic insulating layer 108a.

The buffer layer 101 may be made of an inorganic insulating material. The buffer layer 101 may be one inorganic insulating layer, but may also be formed of two layers according to the wavelength of a laser as illustrated in FIG. 13. For example, the buffer layer 101 may include a first buffer layer 102a disposed on the substrate 10 and a second buffer layer 103a disposed on the first buffer layer 102a. In consideration of process optimization, the first buffer layer 102a may be formed by extending the multi-buffer layer 102 in the display area DA, and the second buffer layer 103a may be formed by extending the active buffer layer 103 in the display area DA; however, the present specification is not necessarily limited thereto. The first buffer layer 102a may be referred to as a lower buffer layer, and the second buffer layer 103a may be referred to as an upper buffer layer.

Accordingly, the buffer layer 101 may include one inorganic insulating layer or one more inorganic insulating layers depending on the type, wavelength, or the like of a laser, and the thickness, material, or the like of the buffer layer 101 may be adjusted. The buffer layer 101 may be disposed on the opening 11 to prevent an etching solution from penetrating into the interior of the display panel 100. The buffer layer 101 may also be disposed on an emission line of a laser emitted before an etching process to prevent damage to the third protruding pattern ST3 caused by the laser.

The first inorganic insulating layer 107 may be made of an inorganic insulating material. The first inorganic insulating layer 107 may be one inorganic insulating layer, but may also be formed of two layers according to the wavelength of a laser as illustrated in FIG. 13. For example, the first inorganic insulating layer 107 may include a first lower inorganic insulating layer 104a disposed on the second buffer layer 103a and a first upper inorganic insulating layer 106a disposed on the first lower inorganic insulating layer 104a.

In consideration of process optimization, the first lower inorganic insulating layer 104a may be formed together when the lower gate insulating layer 104 in the display area DA is formed, and the first upper inorganic insulating layer 106a may be formed together when the upper gate insulating layer 106 in the display area DA is formed.

Accordingly, the first inorganic insulating layer 107 may include one inorganic insulating layer or one more inorganic insulating layers depending on the type, wavelength, or the like of a laser, and the thickness, material, or the like of the first inorganic insulating layer 107 may be adjusted.

The first metal layer 132a may be made of a metal material. The first metal layer 132a may overlap the opening 11 in the Z-axis direction. In such a case, the first metal layer 132a may extend further toward the display area DA than the opening 11. The side surface of the first metal layer 132a may be exposed to the light-transmissive area TA.

The first metal layer 132a may be a single layer or a multi-layer made of any one of molybdenum (Mo), aluminum (Al), chromium (Cr), gold (Au), titanium (Ti), nickel (Ni), neodymium (Nd), and copper (Cu) or an alloy thereof, but is not limited thereto. The first metal layer 132a may be formed together when the second gate electrode 132 is formed.

Because the side surface of the first metal layer 132a is exposed to the light-transmissive area TA, corrosion may occur depending on the material of the first metal layer 132a. However, the display device according to an embodiment of the present specification may prevent corrosion from spreading by disposing the second inorganic insulating layer 108a to cover the first metal layer 132a. For example, because the first metal layer 132a may be disconnected from the second gate electrode 132 by the first inorganic insulating layer 107 and the second inorganic insulating layer 108a, corrosion occurring in the first metal layer 132a does not spread to the second gate electrode 132.

The second inorganic insulating layer 108a may be made of an inorganic insulating material and may be a single layer or a multilayer, but is not limited thereto. The second inorganic insulating layer 108a is formed together when the upper interlayer dielectric layer 108 in the display area DA is formed, so that process optimization may be implemented.

The second metal layer 131a may be made of a metal material. The second metal layer 131a may overlap the first metal layer 132a in the Z-axis direction and may be spaced apart from the first metal layer 132a. In such a case, the second metal layer 131a may extend further toward the display area DA than the opening 11. The side surface of the second metal layer 131a may be exposed to the light-transmissive area TA.

The second metal layer 131a may be a single layer or a multi-layer made of any one of molybdenum (Mo), aluminum (Al), chromium (Cr), gold (Au), titanium (Ti), nickel (Ni), neodymium (Nd), and copper (Cu) or an alloy thereof, but is not limited thereto. The second metal layer 131a may be formed together when the first source and drain electrodes 121 and 124 and the second source and drain electrodes 131 and 134 are formed. Accordingly, the second metal layer 131a may include a first layer made of Ti, a second layer made of Al, and a third layer made of Ti. The second layer may be disposed between the first layer and the third layer.

Because the side surface of the second metal layer 131a is exposed to the light-transmissive area TA, corrosion may occur depending on the material of the second metal layer 131a. For example, the second layer made of Al may be relatively more vulnerable to corrosion than the first layer and the third layer. However, the display device according to an embodiment of the present specification may prevent corrosion from spreading by disposing the planarization layer 110a to cover the second metal layer 131a. For example, because the second metal layer 131a may be disconnected from the first source and drain electrodes 121 and 124 and the second source and drain electrodes 131 and 134 by the second inorganic insulating layer 108a and the planarization layer 110a, corrosion occurring in the second metal layer 131a does not spread to the first source and drain electrodes 121 and 124 and the second source and drain electrodes 131 and 134.

The planarization layer 110a may be disposed on the second inorganic insulating layer 108a to cover the second metal layer 131a. The planarization layer 110a may include an organic insulating material, such as acrylic resin. The planarization layer 110a may be formed when the first planarization layer 110 or the second planarization layer 111 in the display area DA is formed, thereby improving the efficiency of a manufacturing process.

The third protruding pattern ST3 may be disposed on the planarization layer 110a.

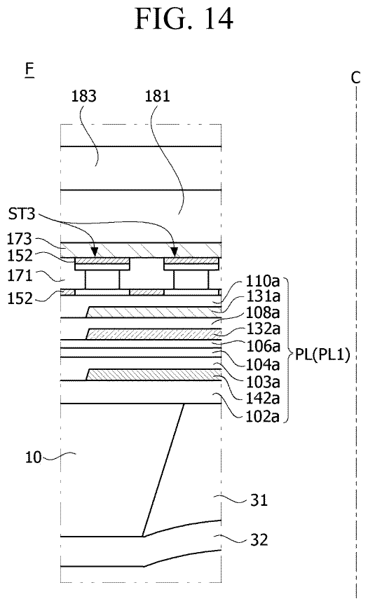

FIG. 14 is a view illustrating another example of a protective layer disposed in the display device according to an embodiment of the present specification. An upper protective layer PL1 illustrated in FIG. 14 may represent a protective layer PL according to a second example. In describing the protective layer PL according to the second example, because the same components as those of the protective layer PL according to the first example may be denoted by the same reference numerals, detailed description thereof will be omitted.

When the protective layer PL according to the first example and the protective layer PL according to the second example are compared with each other with reference to FIGS. 13 and 14, the protective layer PL according to the second example is different from the protective layer PL according to the first example in that a third metal layer 142a is further disposed between the first buffer layer 102a and the second buffer layer 103a.

The third metal layer 142a may be made of a metal material. The third metal layer 142a may overlap the first metal layer 132a and the second metal layer 131a in the Z-axis direction. In such a case, the third metal layer 142a may be disposed below the first metal layer 132a to be spaced apart from the first metal layer 132a, and the second buffer layer 103a may be disposed between the third metal layer 142a and the first metal layer 132a. Accordingly, the third metal layer 142a may more effectively block a laser emitted toward the third protruding pattern ST3.

The third metal layer 142a may be a single layer or a multi-layer made of any one of molybdenum (Mo), aluminum (Al), chromium (Cr), gold (Au), titanium (Ti), nickel (Ni), neodymium (Nd), and copper (Cu) or an alloy thereof, but is not limited thereto. However, considering that a side surface of the third metal layer 142a may be exposed to the light-transmissive area TA and corroded, the third metal layer 142a may be made of molybdenum (Mo) resistant to corrosion. In such a case, because the second buffer layer 103a is disposed to cover the third metal layer 142a, even though corrosion occurs in the third metal layer 142a, the spread of corrosion may be prevented.

The third metal layer 142a may be formed together with the second light blocking layer 142 in consideration of process optimization.

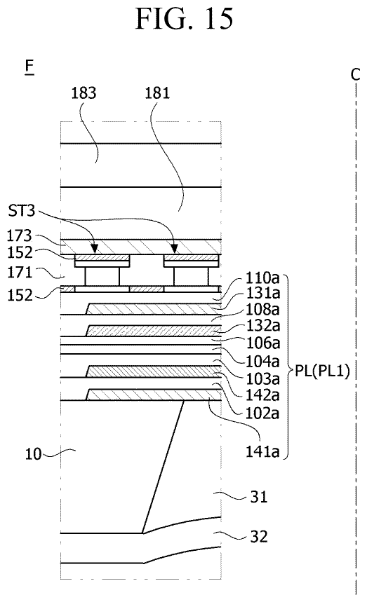

FIG. 15 is a view illustrating still another example of a protective layer disposed in the display device according to an embodiment of the present specification. An upper protective layer PL1 illustrated in FIG. 15 may represent a protective layer PL according to a third example.

In describing the protective layer PL according to the third example, because the same components as those of the protective layer PL according to the second example may be denoted by the same reference numerals, detailed description thereof will be omitted.

When the protective layer PL according to the second example and the protective layer PL according to the third example are compared with each other with reference to FIGS. 14 and 15, the protective layer PL according to the third example is different from the protective layer PL according to the second example in that a fourth metal layer 141a is further disposed between the substrate 10 and the first buffer layer 102a.

The fourth metal layer 141a may be made of a metal material. The fourth metal layer 141a may overlap the first metal layer 132a, the second metal layer 131a, and the third metal layer 142a in the Z-axis direction. In such a case, the fourth metal layer 141a may be disposed below the third metal layer 142a to be spaced apart from the third metal layer 142a, and the first buffer layer 102a may be disposed between the third metal layer 142a and the fourth metal layer 141a. Accordingly, the fourth metal layer 141a may more effectively block a laser emitted toward the third protruding pattern ST3.

The fourth metal layer 141a may be a single layer or a multi-layer made of any one of molybdenum (Mo), aluminum (Al), chromium (Cr), gold (Au), titanium (Ti), nickel (Ni), neodymium (Nd), and copper (Cu) or an alloy thereof, but is not limited thereto. However, considering that a side surface of the fourth metal layer 141a may be exposed to the light-transmissive area TA and corroded, the fourth metal layer 141a may be made of molybdenum (Mo) resistant to corrosion. In such a case, because the first buffer layer 102a is disposed to cover the fourth metal layer 141a, even though corrosion occurs in the fourth metal layer 141a, the spread of corrosion may be prevented. The fourth metal layer 141a may be formed together with the first light blocking layer 141 in consideration of process optimization.

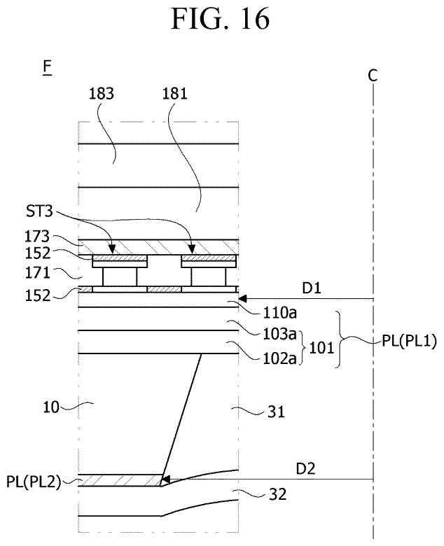

FIG. 16 is a view illustrating yet another example of a protective layer disposed on the display device according to an embodiment of the present specification. An upper protective layer PL1 and a lower protective layer PL2 illustrated in FIG. 16 may represent a protective layer PL according to a fourth example.

With reference to FIG. 16, the display device according to an embodiment of the present specification may include the substrate 10, the upper protective layer PL1 disposed on the substrate 10, the lower protective layer PL2 disposed under the substrate 10, and the third protruding pattern ST3 disposed on the upper protective layer PL1. The opening 11 may be formed in the substrate 10, and the side coating layer 31 may be disposed in the opening 11. The back coating layer 32 may be disposed on the back surface of the lower protective layer PL2.

The upper protective layer PL1 may be disposed on the substrate 10 to protect components, such as the third protruding pattern ST3, disposed on the upper protective layer PL1 from a laser emitted before an etching process. The upper protective layer PL1 may be disposed on the substrate 10 to prevent an etching solution from penetrating into the interior of the display panel 100.

The lower protective layer PL2 may be disposed on the back surface of the substrate 10 to protect components, such as the third protruding pattern ST3, disposed on the upper protective layer PL1 from the laser emitted before the etching process.

A second distance D2 from the center C of the light-transmissive area TA to the lower protective layer PL2 may be greater than a first distance D1 from the center C of the light-transmissive area TA to the upper protective layer PL1. For example, the upper protective layer PL1 may be disposed at the first distance D1 from the center C of the light-transmissive area TA, the lower protective layer PL2 may be disposed at the second distance D2 from the center C of the light-transmissive area TA, and the second distance D2 may be greater than the first distance D1.

The upper protective layer PL1 may include the buffer layer 101 disposed on the substrate 10 and the planarization layer 110a disposed below the third protruding pattern ST3. The buffer layer 101 may be made of an inorganic insulating material, and may include the first buffer layer 102a disposed on the substrate 10 and the second buffer layer 103a disposed on the first buffer layer 102a.

The planarization layer 110a may be disposed on the buffer layer 101. The planarization layer 110a may be made of an organic insulating material, such as acrylic resin. Subsequently, the third protruding pattern ST3 may be disposed on the planarization layer 110a.

The lower protective layer PL2 may be disposed on the back surface of the substrate 10, and may more effectively respond to a laser together with the upper protective layer PL1, and simultaneously protect the upper protective layer PL1 from a laser. For example, when a laser is emitted before an etching process, because the lower protective layer PL2 is preferentially irradiated with the laser, the influence of the laser reaching the upper protective layer PL1 may be reduced. This may reduce the possibility that the buffer layer 101 disposed on the opening 11 is etched by an etching solution.

A non-irradiated area of the lower protective layer PL2, which is not irradiated by a laser, may serve as the mask pattern MP. The lower protective layer PL2 may include at least one of an organic insulating layer made of an organic material, an inorganic insulating layer made of an inorganic material, and a metal layer made of a metal material. The lower protective layer PL2 may be a single layer or a multi-layer, but is not limited thereto.

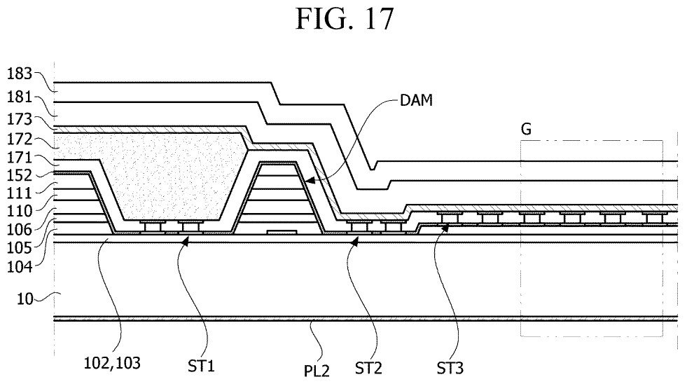

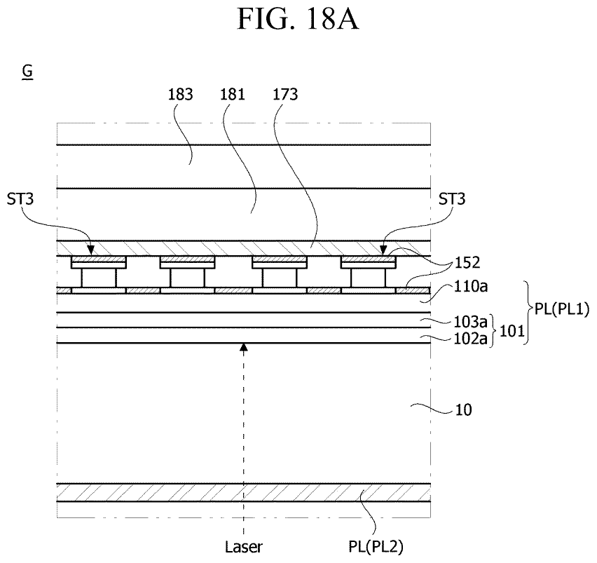

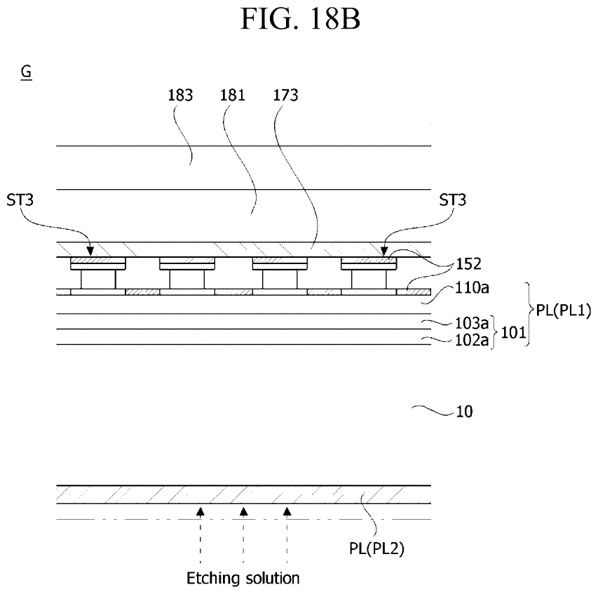

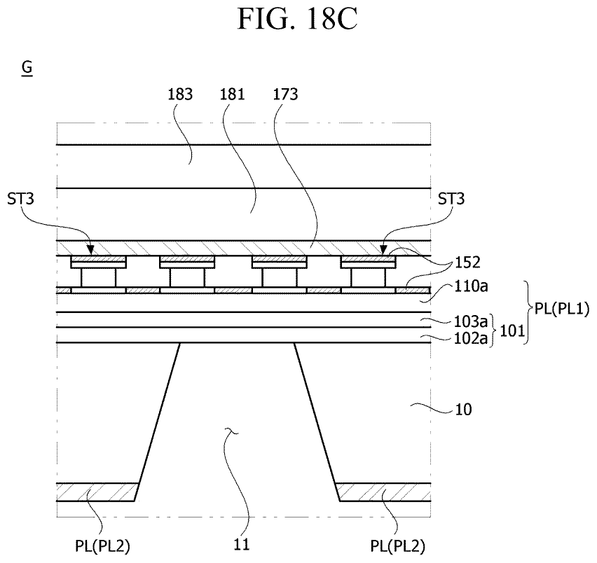

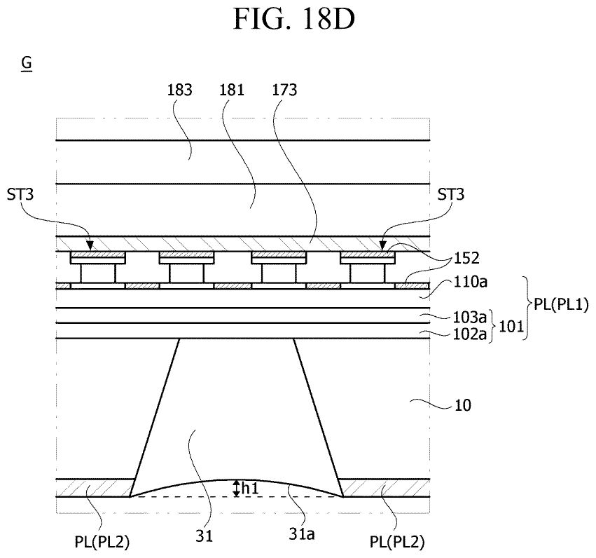

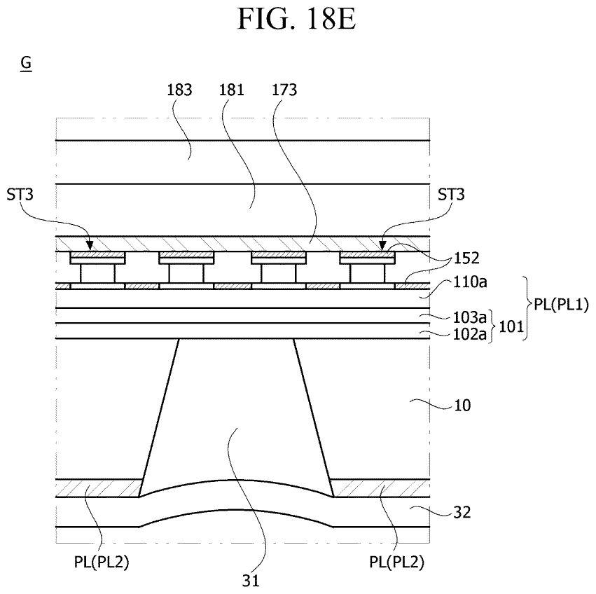

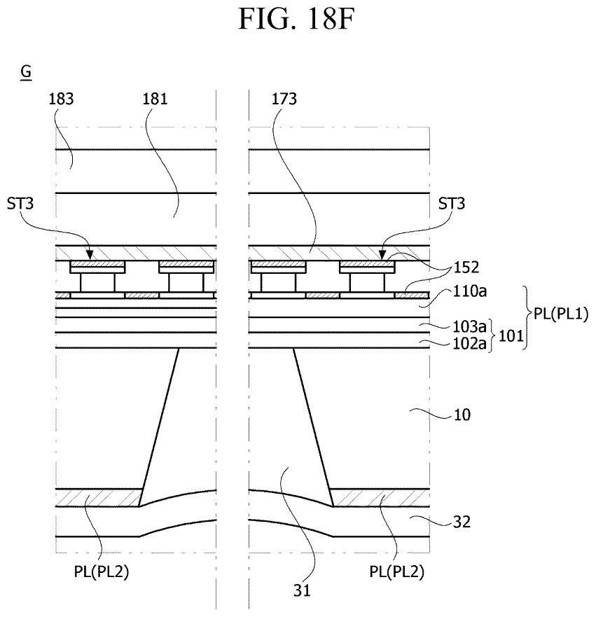

FIG. 17 is a view illustrating another embodiment of a display panel before the light-transmissive area is formed, and FIGS. 18A to 18F are views illustrating a process of etching the substrate to form the light-transmissive area in the display panel on which the lower protective layer is disposed and are views based on an area G in FIG. 17.

When the display panel illustrated in FIG. 17 and the display panel illustrated in FIG. 11 are compared with each other, the display panel illustrated in FIG. 17 is different from the display panel illustrated in FIG. 11 in that the lower protective layer PL2 is disposed instead of the mask pattern MP, and differences in an etching process occur due to the lower protective layer PL2.

FIG. 18A is a view illustrating a step of emitting a laser to the back surface of the substrate on which the lower protective layer is disposed.

With reference to FIGS. 11 and 18A, a laser may be emitted to a preset position on the lower protective layer PL2 to facilitate etching of the substrate 10 using an etching solution. The preset position may be a position where the light-transmissive area TA is to be formed or a position where the opening 11 of the substrate 10 is to be formed.

FIG. 18B is a view illustrating a step of exposing a laser-irradiated area to an etching solution, and FIG. 18C is a view illustrating a step of forming the opening on the back surface of the substrate through an etching process.

With reference to FIGS. 18B and 18C, when an etching solution is brought into contact with an area exposed to a laser, a partial area of the lower protective layer PL2 and the substrate 10 may be etched to form the opening 11. The partial area of the lower protective layer PL2 exposed to the laser may have their properties changed and be etched by the etching solution. Accordingly, the inner side surface of the lower protective layer PL2 may form a part of the opening 11, and include an inclined surface or a curved surface formed by the degree of exposure to the etching solution.

In such a case, the buffer layer 101 formed on the etched substrate 10 may prevent the etching solution from penetrating into the interior of the display panel 100. The buffer layer 101 may be made of an inorganic insulating material, and may be formed of at least one of the multi-buffer layer 102 and the active buffer layer 103 extending from the display area DA in consideration of process optimization; however, the present specification is not necessarily limited thereto. For example, the buffer layer 101 may be formed using a separate inorganic insulating material different from that of the multi-buffer layer 102 and the active buffer layer 103 in the display area DA. In such a case, because the laser preferentially passes through the lower protective layer PL2, a part of the buffer layer 101 may also be etched, but the degree of etching may be slight.

FIG. 18D is a view illustrating a step of disposing the side coating layer in the opening.

As shown in FIG. 18D, the opening 11 of the substrate 10 may be filled with the side coating layer 31. Subsequently, when the side coating layer 31 is cured, the side coating layer 31 shrinks by the certain height h1 and a curvature may be formed on the lower surface 31a of the side coating layer 31. However, the side coating layer 31 may not shrink depending on a material.

FIG. 18E is a view illustrating a step of disposing the back coating layer.

As shown in FIG. 18E, the back coating layer 32 may be entirely formed on the back surface of the lower protective layer PL2 and the back surface of the side coating layer 31. However, the present specification is not necessarily limited thereto, and the back coating layer 32 may be formed only on the back surface of the lower protective layer PL2.

FIG. 18F is a view illustrating a laser cutting step.

With reference to FIG. 18F, the light-transmissive area TA may be formed by irradiating the opening 11 side of the substrate 10 with a laser. In such a case, the upper protective layer PL1 and the third protruding pattern ST3 disposed on the substrate 10 and the lower protective layer PL2 disposed under the substrate 10 may be cut by the laser.

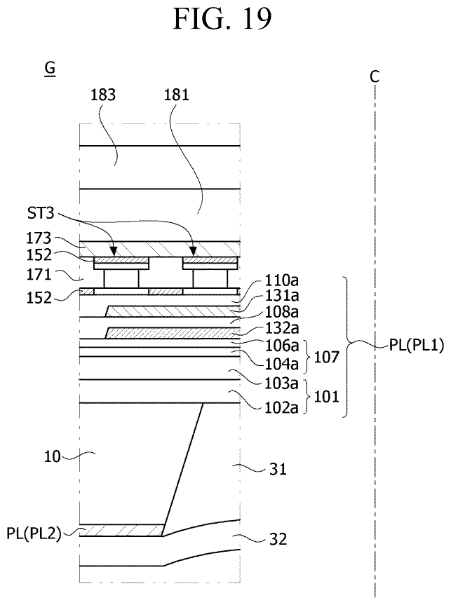

FIG. 19 is a view illustrating yet another example of a protective layer disposed in the display device according to an embodiment of the present specification. An upper protective layer PL1 and a lower protective layer PL2 illustrated in FIG. 19 may represent a protective layer PL according to a fifth embodiment. In describing the protective layer PL according to the fifth example, because the same components as those of the protective layer PL according to the fourth example may be denoted by the same reference numerals, detailed description thereof will be omitted.

When the protective layer PL according to the fourth example and the protective layer PL according to the fifth example are compared with each other with reference to FIGS. 16 and 19, the upper protective layer PL1 in the protective layer PL according to the fifth example is different from the upper protective layer PL1 according to the fourth example in that it further includes the first inorganic insulating layer 107 disposed on the buffer layer 101, the first metal layer 132a disposed on the first inorganic insulating layer 107, the second inorganic insulating layer 108a disposed on the first inorganic insulating layer 107 to cover the first metal layer 132a, and the second metal layer 131a disposed on the second inorganic insulating layer 108a.

The first inorganic insulating layer 107 may be made of an inorganic insulating material, and may be provided as one inorganic insulating layer or two or more inorganic insulating layers. For example, the first inorganic insulating layer 107 may include the first lower inorganic insulating layer 104a disposed on the second buffer layer 103a and the first upper inorganic insulating layer 106a disposed on the first lower inorganic insulating layer 104a. In consideration of process optimization, the first lower inorganic insulating layer 104a may be formed together when the lower gate insulating layer 104 in the display area DA is formed, and the first upper inorganic insulating layer 106a may be formed together when the upper gate insulating layer 106 in the display area DA is formed.

The first metal layer 132a may be made of a metal material. The first metal layer 132a may overlap the opening 11 in the Z-axis direction.

The first metal layer 132a may be a single layer or a multi-layer made of any one of molybdenum (Mo), aluminum (Al), chromium (Cr), gold (Au), titanium (Ti), nickel (Ni), neodymium (Nd), and copper (Cu) or an alloy thereof, but is not limited thereto. The first metal layer 132a may be formed together when the second gate electrode 132 is formed.

The second inorganic insulating layer 108a may be made of an inorganic insulating material and may be a single layer or a multilayer, but is not limited thereto. The second inorganic insulating layer 108a is formed together when an upper interlayer dielectric layer 108 in the display area DA is formed, so that process optimization may be implemented.

The second metal layer 131a may be made of a metal material. The second metal layer 131a may overlap the first metal layer 132a in the Z-axis direction and may be spaced apart from the first metal layer 132a.

The second metal layer 131a may be formed together when the first source and drain electrodes 121 and 124 and the second source and drain electrodes 131 and 134 are formed. Accordingly, the second metal layer 131a may include a first layer made of Ti, a second layer made of Al, and a third layer made of Ti. The second layer may be disposed between the first layer and the third layer.

The planarization layer 110a may be disposed on the second inorganic insulating layer 108a to cover the second metal layer 131a. The planarization layer 110a may include an organic insulating material, such as acrylic resin. The planarization layer 110a may be formed when the first planarization layer 110 or the second planarization layer 111 in the display area DA is formed, thereby improving the efficiency of a manufacturing process.

The third protruding pattern ST3 may be disposed on the planarization layer 110a.

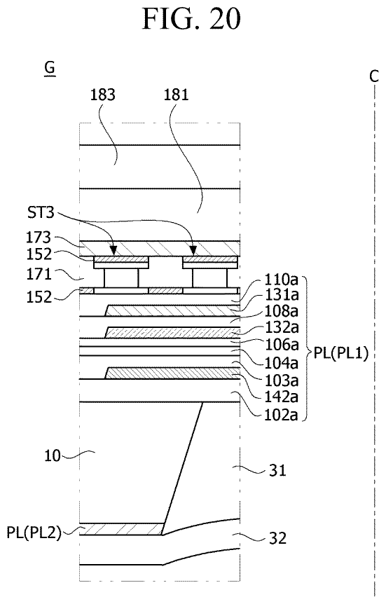

FIG. 20 is a view illustrating yet another example of a protective layer disposed in the display device according to an embodiment of the present specification. An upper protective layer PL1 and a lower protective layer PL2 illustrated in FIG. 20 may represent a protective layer PL according to a sixth example. In describing the protective layer PL according to the sixth example, because the same components as those of the protective layer PL according to the fifth example may be denoted by the same reference numerals, detailed description thereof will be omitted.

When the protective layer PL according to the fifth example and the protective layer PL according to the sixth example are compared with each other with reference to FIGS. 19 and 20, the protective layer PL according to the sixth example is different from the protective layer PL according to the fifth example in that the third metal layer 142a is further disposed between the first buffer layer 102a and the second buffer layer 103a.

The third metal layer 142a may be made of a metal material. The third metal layer 142a may overlap the first metal layer 132a and the second metal layer 131a in the Z-axis direction. In such a case, the third metal layer 142a may be disposed below the first metal layer 132a to be spaced apart from the first metal layer 132a, and the second buffer layer 103a may be disposed between the third metal layer 142a and the first metal layer 132a. Accordingly, the third metal layer 142a may more effectively block a laser emitted toward the third protruding pattern ST3.

The third metal layer 142a may be a single layer or a multi-layer made of any one of molybdenum (Mo), aluminum (Al), chromium (Cr), gold (Au), titanium (Ti), nickel (Ni), neodymium (Nd), and copper (Cu) or an alloy thereof, but is not limited thereto. However, considering that a side surface of the third metal layer 142a may be exposed to the light-transmissive area TA and corroded, the third metal layer 142a may be made of molybdenum (Mo) resistant to corrosion. In such a case, because the second buffer layer 103a is disposed to cover the third metal layer 142a, even though corrosion occurs in the third metal layer 142a, the spread of corrosion may be prevented. The third metal layer 142a may be formed together with the second light blocking layer 142 in consideration of process optimization.

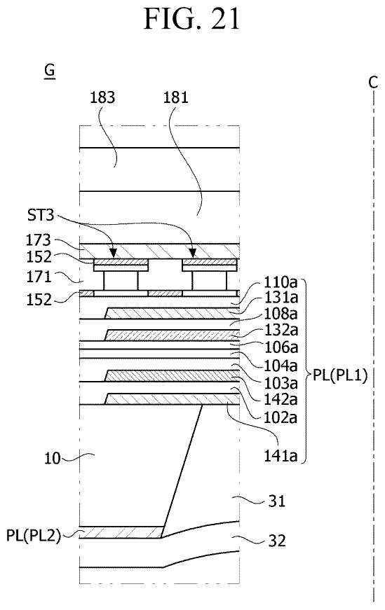

FIG. 21 is a view illustrating yet another example of a protective layer disposed in the display device according to an embodiment of the present specification. An upper protective layer PL1 and a lower protective layer PL2 illustrated in FIG. 20 may represent a protective layer PL according to a seventh example. In describing the protective layer PL according to the seventh example, because the same components as those of the protective layer PL according to the sixth example may be denoted by the same reference numerals, detailed description thereof will be omitted.

When the protective layer PL according to the seventh example and the protective layer PL according to the sixth example are compared with each other with reference to FIGS. 20 and 21, the protective layer PL according to the seventh example is different from the protective layer PL according to the sixth example in that the fourth metal layer 141a is further disposed between the substrate 10 and the first buffer layer 102a.

The fourth metal layer 141a may be made of a metal material. The fourth metal layer 141a may overlap the first metal layer 132a, the second metal layer 131a, and the third metal layer 142a in the Z-axis direction. In such a case, the fourth metal layer 141a may be disposed below the third metal layer 142a to be spaced apart from the third metal layer 142a, and the first buffer layer 102a may be disposed between the third metal layer 142a and the fourth metal layer 141a. Accordingly, the fourth metal layer 141a may more effectively block a laser emitted toward the third protruding pattern ST3.

The fourth metal layer 141a may be a single layer or a multi-layer made of any one of molybdenum (Mo), aluminum (Al), chromium (Cr), gold (Au), titanium (Ti), nickel (Ni), neodymium (Nd), and copper (Cu) or an alloy thereof, but is not limited thereto. However, considering that the side surface of the fourth metal layer 141a may be exposed to the light-transmissive area TA and corroded, the fourth metal layer 141a may be made of molybdenum (Mo) resistant to corrosion. In such a case, because the first buffer layer 102a is disposed to cover the fourth metal layer 141a, even though corrosion occurs in the fourth metal layer 141a, the spread of corrosion may be prevented. The fourth metal layer 141a may be formed together with the first light blocking layer 141 in consideration of process optimization.

A display device according to one or more embodiments of the present specification may be described as follows.

A display device according to one or more embodiments of the present specification may include: a display panel including a display area, a light-transmissive area, and a non-display area surrounding the light-transmissive area; and a sensor disposed in the light-transmissive area, wherein the display panel may include: a substrate; a circuit portion and a light-emitting element part on the substrate in the display area; an upper protective layer on the substrate in the non-display area; and a plurality of protruding patterns on the upper protective layer, and wherein the substrate may include an opening at a position corresponding to the light-transmissive area.

The upper protective layer may include at least one of an organic insulating layer, an inorganic insulating layer, and a metal layer.

The upper protective layer may include: a buffer layer on the substrate; a planarization layer below the plurality of protruding patterns; and an inorganic insulating layer and a metal layer disposed between the buffer layer and the planarization layer, and the planarization layer may be an organic insulating layer.

The inorganic insulating layer and the metal layer may include: a first inorganic insulating layer on the buffer layer; a first metal layer on the first inorganic insulating layer; a second inorganic insulating layer on the first inorganic insulating layer to cover the first metal layer; and a second metal layer on the second inorganic insulating layer.

The buffer layer may include a lower buffer layer and an upper buffer layer on the lower buffer layer, and the upper protective layer may further include a third metal layer between the lower buffer layer and the upper buffer layer.

The upper protective layer may further include a fourth metal layer between the substrate and the lower buffer layer.

The fourth metal layer may be disposed to cover an upper portion of the opening.

The third metal layer or the fourth metal layer may include molybdenum.

The display panel may further include a lower protective layer disposed under the substrate in the non-display area, and the lower protective layer may include at least one of an organic insulating layer, an inorganic insulating layer, and a metal layer.

A distance from a center of the light-transmissive area to the lower protective layer may be greater than a distance from the center of the light-transmissive area to the upper protective layer.

The upper protective layer may include a protrusion protruding toward a center of the light-transmissive area from an inner side of the opening.

A dam may be in the non-display area, and the plurality of protruding patterns include: a plurality of first protruding patterns between the display area and the dam; a plurality of second protruding patterns between the dam and the upper protective layer; and a plurality of third protruding patterns on the upper protective layer.

At least one of the plurality of first protruding patterns, the plurality of second protruding patterns, and the plurality of third protruding patterns may have a different shape or material than other ones of the plurality of first protruding patterns, the plurality of second protruding patterns, and the plurality of third protruding patterns.

The plurality of protruding patterns may be formed to have an undercut shape, and an inorganic insulating layer may be between the plurality of protruding patterns.

The plurality of protruding patterns may be formed to have a layer structure equal to a layer structure of a connection electrode of the circuit portion.

A coating layer may be further disposed in the opening.

A display device according to one or more embodiment of the present specification may include: a display panel including a display area, a light-transmissive area, and a non-display area surrounding the light-transmissive area; and a sensor in the light-transmissive area, wherein the display panel may include: a substrate having an opening at a position corresponding to the light-transmissive area; a circuit portion and a light-emitting element part on the substrate in the display area; a buffer layer on the substrate in the non-display area; a lower protective layer under the substrate in the non-display area; a planarization layer on the buffer layer; and a plurality of protruding patterns on the planarization layer, wherein a distance from a center of the light-transmissive area to the lower protective layer is greater than a distance from the center of the light-transmissive area to the buffer layer.

The display panel may include: a first inorganic insulating layer on the buffer layer; a first metal layer on the first inorganic insulating layer; a second inorganic insulating layer on the first inorganic insulating layer to cover the first metal layer; and a second metal layer on the second inorganic insulating layer.

The buffer layer may include a lower buffer layer, an upper buffer layer on the lower buffer layer, and a third metal layer between the lower buffer layer and the upper buffer layer.

The display panel may further include a fourth metal layer between the substrate and the lower buffer layer.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a display panel including a display area, a light-transmissive area, and a non-display area surrounding the light-transmissive area,
wherein the display panel includes:
a substrate;
a circuit portion and a light-emitting element part on the substrate in the display area;
an upper protective layer on the substrate in the non-display area; and
a plurality of protruding patterns on the upper protective layer, and
wherein the substrate includes an opening at a position corresponding to the light-transmissive area.

2. The display device of claim 1, wherein the upper protective layer includes at least one of an organic insulating layer, an inorganic insulating layer, and a metal layer.

3. The display device of claim 1, wherein the upper protective layer includes:
a buffer layer on the substrate;
a planarization layer below the plurality of protruding patterns; and
an inorganic insulating layer and a metal layer between the buffer layer and the planarization layer, and
wherein the planarization layer is an organic insulating layer.

4. The display device of claim 3, wherein the inorganic insulating layer and the metal layer include:
a first inorganic insulating layer on the buffer layer;
a first metal layer on the first inorganic insulating layer;
a second inorganic insulating layer on the first inorganic insulating layer to cover the first metal layer; and
a second metal layer on the second inorganic insulating layer.

5. The display device of claim 4, wherein the buffer layer includes a lower buffer layer and an upper buffer layer on the lower buffer layer, and
the upper protective layer further includes a third metal layer between the lower buffer layer and the upper buffer layer.

6. The display device of claim 5, wherein the upper protective layer further includes a fourth metal layer between the substrate and the lower buffer layer.

7. The display device of claim 6, wherein the fourth metal layer covers an upper portion of the opening.

8. The display device of claim 6, wherein the third metal layer or the fourth metal layer includes molybdenum.

9. The display device of claim 1, wherein the display panel further includes a lower protective layer disposed under the substrate in the non-display area, and
wherein the lower protective layer includes at least one of an organic insulating layer, an inorganic insulating layer, and a metal layer.

10. The display device of claim 9, wherein a distance from a center of the light-transmissive area to the lower protective layer is greater than a distance from the center of the light-transmissive area to the upper protective layer.

11. The display device of claim 1, wherein the upper protective layer includes a protrusion protruding toward a center of the light-transmissive area from an inner side of the opening.

12. The display device of claim 1, further comprising:
a dam in the non-display area,
wherein the plurality of protruding patterns include:
a plurality of first protruding patterns between the display area and the dam;
a plurality of second protruding patterns between the dam and the upper protective layer; and
a plurality of third protruding patterns on the upper protective layer.

13. The display device of claim 12, wherein at least one of the plurality of first protruding patterns, the plurality of second protruding patterns, and the plurality of third protruding patterns has a different shape or material than other ones of the plurality of first protruding patterns, the plurality of second protruding patterns, and the plurality of third protruding patterns.

14. The display device of claim 1, wherein the plurality of protruding patterns include an undercut shape, and
wherein an inorganic insulating layer is between the plurality of protruding patterns.

15. The display device of claim 1, wherein the plurality of protruding patterns have a layer structure equal to a layer structure of a connection electrode of the circuit portion.

16. The display device of claim 1, wherein a coating layer is further disposed in the opening.

17. A display device, comprising:
a display panel including a display area, a light-transmissive area, and a non-display area surrounding the light-transmissive area,
wherein the display panel includes:
a substrate having an opening at a position corresponding to the light-transmissive area;
a circuit portion and a light-emitting element part on the substrate in the display area;
a buffer layer on the substrate in the non-display area;
a lower protective layer under the substrate in the non-display area;
a planarization layer on the buffer layer; and
a plurality of protruding patterns on the planarization layer, and
wherein a distance from a center of the light-transmissive area to the lower protective layer is greater than a distance from the center of the light-transmissive area to the buffer layer.

18. The display device of claim 17, wherein the display panel further includes:
a first inorganic insulating layer on the buffer layer;
a first metal layer on the first inorganic insulating layer;
a second inorganic insulating layer on the first inorganic insulating layer to cover the first metal layer; and
a second metal layer on the second inorganic insulating layer.

19. The display device of claim 18, wherein the buffer layer includes a lower buffer layer, an upper buffer layer on the lower buffer layer, and a third metal layer disposed between the lower buffer layer and the upper buffer layer.

20. The display device of claim 19, wherein the display panel further includes a fourth metal layer between the substrate and the lower buffer layer.
